(19) United States
(12) Patent Application Publication
(10) Pub. No.: US 2023/0411568 A1
(43) Pub. Date: Dec. 21, 2023

(54) DISPLAY DEVICE

(71) Applicant: Samsung Display Co., LTD., Yongin-si (KR)

(72) Inventors: Jeong Hyun LEE, Yongin-si (KR); Jin Woo LEE, Yongin-si (KR); Zu Seok OH, Yongin-si (KR); Seung Jin CHU, Yongin-si, (KR)

(73) Assignee: Samsung Display Co., LTD., Yongin-si (KR)

(21) Appl. No.: 18/304,608

(22) Filed: Apr. 21, 2023

(30) Foreign Application Priority Data
Jun. 17, 2022 (KR) 10-2022-0073865

(51) Int. Cl. H01L 33/50; H01L 25/075; H01L 33/62

(52) U.S. Cl. CPC H01L 33/505; H01L 33/62; H01L 25/0753

(57) ABSTRACT

A display device in accordance with an embodiment may include light emitting elements on a base layer; a bank on the base layer and protruding in a thickness direction of the base layer; and a color conversion layer on the light emitting elements in an area adjacent to the bank, the color conversion layer including quantum dots that convert a color of a light. The bank may include a main body and protrusions protruding from the main body toward the light emitting elements.

### CROSS-REFERENCE TO RELATED APPLICATION

The application claims priority to and benefits of Korean patent application No. 10-2022-0073865 under 35 U.S.C. § 119, filed in the Korean Intellectual Property Office on Jun. 17, 2022, the entire contents of which are incorporated herein by reference.

### BACKGROUND

### 1. Field of Invention

The disclosure relates to a display device capable of uniformly emitting light and improving luminance.

### 2. Description of the Related Art

The importance of display devices as communication media, has been emphasized because of the increasing developments of information technology. Also, users of display devices for displaying images have been increasing and becoming more popular.

It is to be understood that this background of the technology section is, in part, intended to provide useful background for understanding the technology. However, this background of the technology section may also include ideas, concepts, or recognitions that were not part of what was appreciated by those skilled in the pertinent art prior to a corresponding effective filing date of the subject matter disclosed herein.

### SUMMARY

Embodiments provide a display device capable of uniformly emitting light and improving luminance.

However, embodiments of the disclosure are not limited to those set forth herein. The above and other embodiments will become more apparent to one of ordinary skill in the art to which the disclosure pertains by referencing the detailed description of the disclosure given below.

An embodiment of the disclosure may provide a display device including light emitting elements on a base layer; a bank on the base layer and protruding in a thickness direction of the base layer; and a color conversion layer on the light emitting elements in an area adjacent to the bank, the color conversion layer including quantum dots that convert a color of a light. The bank may include a main body and protrusions protruding from the main body toward the light emitting elements.

In an embodiment, the bank may include a cavity portion between the protrusions and the cavity portion may have a valley structure.

In an embodiment, a peripheral shape of the color conversion layer and a peripheral shape of the bank may correspond to each other, in a plan view.

In an embodiment, the display device may further include a color filter layer including color filters; and light blocking layers between the color filters. Each of the color filters may selectively transmit a light of a color. The bank may define emission areas. The light blocking layers may define sub-pixel areas. The sub-pixel areas and the emission areas may be different from each other.

In an embodiment, lights of different colors that are visible from an outside may be respectively provided from the sub-pixel areas.

In an embodiment, each of the sub-pixel areas may be greater than each of the emission areas. At least part of each of the sub-pixel areas may not overlap each of the emission areas, in a plan view.

In an embodiment, each of the sub-pixel areas may cover an entire area of each of the emission areas.

In an embodiment, the bank may cover an entire area of the light blocking layer, in a plan view.

In an embodiment, the protrusions may have at least one shape of a rectangular shape, a trapezoidal shape, and a triangular shape.

In an embodiment, the cavity portion may include an end area having a U-shape.

In an embodiment, the light emitting elements may be arranged in a direction. Ends of the light emitting elements may be aligned in an element alignment line. A first distance that is a shortest distance between the element alignment line and the protrusions may be about 5 μm or less.

In an embodiment, each of the protrusions may have a pillar shape extending in the thickness direction of the base layer.

In an embodiment, the light emitting elements may form an emission component including a first side and a second side. The protrusions may include first protrusions corresponding to the first side, and second protrusions corresponding to the second side. A shortest distance between the first side of the emission component and the first protrusions may be less than a shortest distance between the second side of the emission component and the second protrusions.

In an embodiment, the light emitting elements may form an emission component including a first side and a second side. The protrusions may include first protrusions corresponding to the first side, and second protrusions corresponding to the second side. A density of the first protrusions on the main body may be greater than a density of the second protrusions on the main body.

In an embodiment, a direction in which the first side extends may be substantially identical to a direction in which the light emitting elements are successively arranged. A direction in which the second side extends may be substantially identical to a direction in which the light emitting elements extend.

In an embodiment, the display device may further include electrodes between the base layer and the light emitting elements. A direction in which the first side extends may be substantially identical to a direction in which the electrodes extend in an area in which the emission component is disposed.

In an embodiment, a direction in which the second side extends may be substantially identical to a direction in which the electrodes are spaced apart from each other in the area in which the emission component is disposed.

In an embodiment, the display device may further include electrodes between the base layer and the light emitting elements; a first connection electrode electrically connected to a first end of each of the light emitting elements; and a second connection electrode electrically connected to a second end of each of the light emitting elements.

In an embodiment, the display device may further include a color filter layer including color filters. Each of the color filters may selectively transmit a light of a color. The color conversion layer may be between the base layer and the color filter layer.

An embodiment of the disclosure may provide a display device including light emitting elements provided on a base layer; a color conversion layer on the light emitting elements and converting a wavelength of a light provided from the light emitting elements; and a bank adjacent to at least part of the color conversion layer. A side surface of the bank that faces the color conversion layer may have a curved surface.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 is a schematic perspective view illustrating a light emitting element in accordance with an embodiment;

FIG. 2 is a schematic sectional view illustrating the light emitting element in accordance with an embodiment;

FIG. 3 is a schematic plan view illustrating a display device in accordance with an embodiment;

FIG. 4 is a schematic block diagram illustrating a display device in accordance with an embodiment;

FIGS. 5 and 6 are schematic plan views illustrating a pixel in accordance with an embodiment;

FIG. 7 is a schematic diagram of an equivalent circuit illustrating a pixel in accordance with an embodiment;

FIG. 8 is a schematic plan view illustrating a sub-pixel in accordance with an embodiment;

FIG. 9 is a schematic sectional view taken along line A-A′ of FIG. 8;

FIG. 10 is a schematic sectional view taken along line B-B′ of FIG. 8;

FIG. 11 is a schematic sectional view taken along line C-C′ of FIG. 5;

FIGS. 12 to 15 are schematic enlarged views of area EA1 of FIG. 6;

FIG. 16 is a schematic perspective view illustrating a second bank in accordance with an embodiment;

FIG. 17 is a schematic enlarged view of area EA2 of FIG. 6; and

FIG. 18 is a schematic enlarged view of area EA2 of FIG. 6, and is a schematic plan view illustrating a pixel having a partially modified structure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

Although the terms “first,” “second,” and the like may be used herein to describe various elements, these elements should not be limited by these terms. These terms are used to distinguish one element from another element. For instance, a first element discussed below could be termed a second element without departing from the teachings of the disclosure. Similarly, the second element could also be termed the first element.

In the disclosure, the singular forms are intended to include the plural forms as well, unless the context clearly indicates otherwise.

It will be further understood that the terms “comprise”, “include”, “have”, etc. when used in the disclosure, specify the presence of stated features, integers, steps, operations, elements, components, and/or combinations of them but do not preclude the presence or addition of one or more other features, integers, steps, operations, elements, components, and/or combinations thereof. Furthermore, in case that a first part such as a layer, a film, a region, or a plate is disposed on a second part, the first part may be not only directly on the second part but a third part may intervene between them. In addition, when it is expressed that a first part such as a layer, a film, a region, or a plate is formed on a second part, the surface of the second part on which the first part is formed is not limited to an upper surface of the second part but may include other surfaces such as a side surface or a lower surface of the second part. To the contrary, in case that a first part such as a layer, a film, a region, or a plate is under a second part, the first part may be not only directly under the second part but a third part may intervene between them.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Various embodiments of the disclosure relate to a display device. Hereinafter, a display device in accordance with an embodiment is described with reference to the attached drawings.

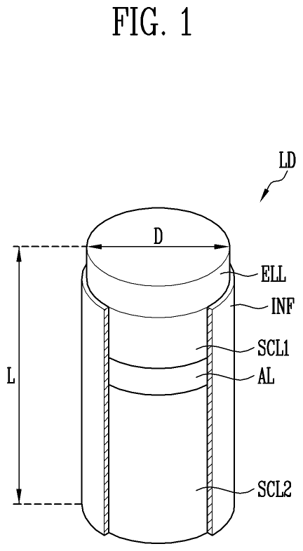

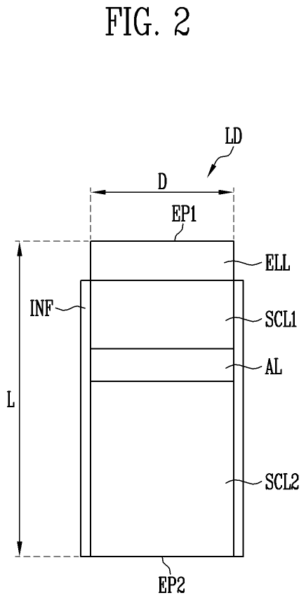

A light emitting element LD in accordance with an embodiment is described with reference to FIGS. 1 and 2. FIG. 1 is a schematic perspective view illustrating the light emitting element LD in accordance with an embodiment. FIG. 2 is a schematic sectional view illustrating the light emitting element LD in accordance with an embodiment.

In accordance with an embodiment, the light emitting element LD may emit light. For example, the light emitting element LD may be a light emitting diode including inorganic material.

The light emitting element LD may have various shapes. For example, the light emitting element LD may have a shape extending in a direction. In an embodiment, FIGS. 1 and 2 illustrate a pillar-like light emitting element LD. However, the type and shape of the light emitting element LD are not limited to the foregoing examples.

The light emitting element LD may include a first semiconductor layer SCL1, a second semiconductor layer SCL2, and an active layer AL disposed between the first and second semiconductor layers SCL1 and SCL2. For example, a direction in which the light emitting element LD extends may refer to a longitudinal direction (L), and the light emitting element LD may include the first semiconductor layer SCL1, the active layer AL, and the second semiconductor layer SCL2 which are successively stacked each other in the longitudinal direction (L). The light emitting element LD may further include an electrode layer ELL and an element insulating layer INF.

The light emitting element LD may be provided in a pillar-like shape extending in a direction. The light emitting element LD may include a first end EP1 and a second end EP2. The first semiconductor layer SCL1 may be adjacent to the first end EP1 of the light emitting element LD. The second semiconductor layer SCL2 may be adjacent to the second end EP2. The electrode layer ELL may be adjacent to the first end EP1.

The light emitting element LD may be a light emitting element fabricated in a pillar-like shape through an etching process. The term “pillar-like shape” may include a rod-like shape and a bar-like shape such as a cylindrical shape, a prismatic shape, or the like, which is longer in a longitudinal direction L (i.e., to have an aspect ratio greater than 1). However, the cross-sectional shape thereof is not limited to a particular shape. For example, the length L of the light emitting element LD may be greater than a diameter D thereof (or a width of the cross-section thereof).

The light emitting element LD may have a size in a range of the nanometer scale to the micrometer scale. For example, the light emitting element LD may have a diameter D (or a width) and/or a length L ranging from the nanometer scale to the micrometer scale. However, the size of the light emitting element LD is not limited thereto.

The first semiconductor layer SCL1 may be a first conductive semiconductor layer. The first semiconductor layer SCL1 may be disposed on the active layer AL and include a semiconductor layer having a type different from that of the second semiconductor layer SCL2. For example, the first semiconductor layer SCL1 may include a P-type semiconductor layer. For instance, the first semiconductor layer SCL1 may include a P-type semiconductor layer which includes at least one semiconductor material of InAlGaN, GaN, AlGaN, InGaN, AlN, and InN, and is doped with a first conductive dopant such as Mg. However, the material for forming the first semiconductor layer SCL1 is not limited thereto, and the first semiconductor layer SCL1 may be formed of various other materials.

The active layer AL may be disposed between the first semiconductor layer SCL1 and the second semiconductor layer SCL2, and have a single-quantum well structure or a multi-quantum well structure. The location of the active layer AL may be changed in various ways depending on the type of the light emitting element LD, rather than being limited to a specific example.

A cladding layer doped with a conductive dopant may be formed on and/or under the active layer AL. For example, the cladding layer may be formed of an AlGaN layer or an InAlGaN layer. In an embodiment, material such as AlGaN or InAlGaN may be used to form the active layer AL. However, the disclosure is not limited thereto, and various other materials may be used to form the active layer AL.

The second semiconductor layer SCL2 may be a second conductive semiconductor layer. The second semiconductor layer SCL2 may be disposed on the active layer AL and include a semiconductor layer of a type different from that of the first semiconductor layer SCL1. For example, the second semiconductor layer SCL2 may include an N-type semiconductor layer. For instance, the second semiconductor layer SCL2 may include at least one semiconductor material of InAlGaN, GaN, AlGaN, InGaN, AlN, and InN, and may include an N-type semiconductor layer doped with a second conductive dopant such as Si, Ge, or Sn. However, the material for forming the second semiconductor layer SCL2 is not limited thereto, and the second semiconductor layer SCL2 may be formed of various other materials.

In case that a voltage equal to or greater than a threshold voltage is applied between the opposite ends (e.g., the first end EP1 and the second end EP2) of the light emitting element LD, electron-hole pairs may be coupled in the active layer AL and the light emitting element LD may emit light. Since light emission of the light emitting element LD may be controlled based on the foregoing principle, the light emitting element LD may be used as a light source of various light emitting devices as well as a pixel of the display device.

The element insulating layer INF may be disposed on a surface of the light emitting element LD. The element insulating layer INF may be formed on the surface of the light emitting element LD and adjacent to (e.g., surround or enclose) an outer circumferential surface of at least the active layer AL. The element insulating layer INF may further enclose areas of the first and second semiconductor layers SCL1 and SCL2. The element insulating layer INF may be formed of a single-layer or double-layer structure, but the disclosure is not limited thereto. The element insulating layer INF may be formed of multiple layers. For example, the element insulating layer INF may include a first insulating layer including a first material and a second insulating layer including a second material different from the first material.

The element insulating layer INF may allow the opposite ends (or the first end EP1 and the second end EP2) of the light emitting element LD which have different polarities to be exposed to the outside. For example, the element insulating layer INF may allow an end of each of the electrode layer ELL and the second semiconductor layer SCL2 which are adjacent to the first and second ends EP1 and EP2 of the light emitting element LD to be exposed.

The element insulating layer INF may include at least one insulating material of silicon oxide (SiOₓ), silicon nitride (SiNₓ), silicon oxynitride (SiOₓN_{y}), aluminum oxide (AlOₓ), and titanium oxide (TiOₓ). The element insulating layer INF may have a single-layer or multi-layer structure. However, the disclosure is not limited to the foregoing example. For example, in an embodiment, the element insulating layer INF may be omitted.

In an embodiment, in case that the element insulating layer INF covers a surface of the light emitting element LD (e.g., an outer surface of the active layer AL), electrical stability of the light emitting element LD may be secured. In case that the element insulating layer INF is provided on the surface of the light emitting element LD, occurrence of a defect on the surface of the light emitting element LD may be minimized, and the lifetime and efficiency of the light emitting element LD may be improved. Even in case that multiple light emitting elements LD are disposed adjacent to each other, an undesired short-circuit may be prevented from occurring between the light emitting elements LD.

The electrode layer ELL may be disposed on the first semiconductor layer SCL1. The electrode layer ELL may be adjacent to the first end EP1. The electrode layer ELL may be electrically connected to the first semiconductor layer SCL1.

A portion of the electrode layer ELL may be exposed. For example, the element insulating layer INF may allow one surface of the electrode layer ELL to be exposed. The electrode layer ELL may be exposed in an area corresponding to the first end EP1.

In an embodiment, a side surface of the electrode layer ELL may be exposed. For example, the element insulating layer INF may cover a side surface of each of the first semiconductor layer SCL1, the active layer AL, and the second semiconductor layer SCL2, and may not cover at least part of the side surface of the electrode layer ELL. In this case, electrical connection for other components of the electrode layer ELL adjacent to the first end EP1 may be facilitated. In an embodiment, the element insulating layer INF may allow not only the side surface of the electrode layer ELL but also a portion of the side surface of the first semiconductor layer SCL1 and/or the second semiconductor layer SCL2 to be exposed.

In an embodiment, the electrode layer ELL may be an ohmic contact electrode. However, the disclosure is not limited to the foregoing example. For example, the electrode layer ELL may be a Schottky contact electrode.

In an embodiment, the electrode layer ELL may include at least one of chrome (Cr), titanium (Ti), aluminum (Al), gold (Au), nickel (Ni), an oxide thereof, and an alloy thereof. However, the disclosure is not limited to the foregoing example. In an embodiment, the electrode layer 14 may be substantially transparent. For example, the electrode layer ELL may include indium tin oxide (ITO). Hence, the emitted light may pass through the electrode layer ELL.

The structure, the shape, and the like of the light emitting element LD are not limited to the foregoing examples. In an embodiment, the light emitting element LD may have various structures and shapes. For example, the light emitting element LD may further include an additional electrode layer which is disposed on a surface of the second semiconductor layer SCL2 and is adjacent to the second end EP2.

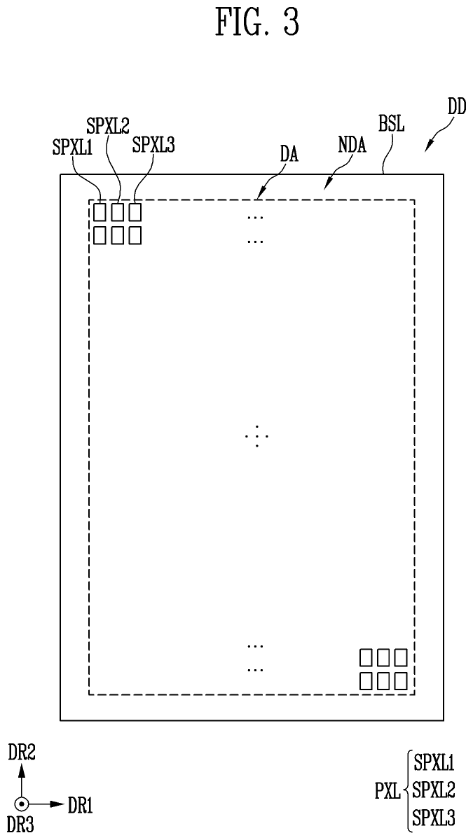

FIG. 3 is a schematic plan view illustrating a display device DD in accordance with an embodiment.

Referring to FIG. 3, the display device DD may include a base layer BSL, and pixels PXL disposed on the base layer BSL. Although not illustrated in the drawing, the display device DD may further include a driving circuit component (e.g., a scan driver and a data driver), lines, and pads which are configured to drive the pixels PXL.

The display device DD may include a display area DA and a non-display area NDA. The non-display area NDA may refer to an area other than the display area DA. The non-display area NDA may be adjacent to (e.g., surround or enclose) at least part of the display area DA.

The base layer BSL may form a base of the display device DD. The base layer BSL may be a rigid or flexible substrate or film. For example, the base layer BSL may be a rigid substrate made of glass or reinforced glass, a flexible substrate (or a thin film) formed of plastic or metal, or at least one insulating layer. The material and/or properties of the base layer BSL are not particularly limited. In an embodiment, the base layer BSL may be substantially transparent. The words “substantially transparent” may mean that light may pass through the substrate SUB at a certain transmissivity or more. In an embodiment, the base layer BSL may be translucent or opaque. The base layer BSL may include reflective material in some embodiments.

The display area DA may refer to an area in which the pixels PXL are disposed. The non-display area NDA may refer to an area in which the pixels PXL are not disposed. The driving circuit layer, the lines, and the pads which are electrically connected to the pixels PXL of the display area DA may be disposed in the non-display area NDA.

In an embodiment, the pixels PXL may be arranged in a stripe or PENTILE™ arrangement structure or the like, but the disclosure is not limited thereto. Various embodiments may be applied to the disclosure.

In an embodiment, the pixel PXL may include a first sub-pixel SPXL1, a second sub-pixel SPXL2, and a third sub-pixel SPXL3. The first sub-pixel SPXL1, the second sub-pixel SPXL2, and the third sub-pixel SPXL3 each may be a sub-pixel. At least one first sub-pixel SPXL1, at least one second sub-pixel SPXL2, and at least one third sub-pixel SPXL3 may form a pixel unit which may emit various colors of light.

For example, the first sub-pixel SPXL1, the second sub-pixel SPXL2, and the third sub-pixel SPXL3 each may emit light of a color (e.g., a certain or selectable color). For instance, the first sub-pixel SPXL1 may be a red pixel configured to emit red (e.g., first color) light, the second sub-pixel SPXL2 may be a green pixel configured to emit green (e.g., second color) light, and the third sub-pixel SPXL3 may be a blue pixel configured to emit blue (e.g., third color) light. In an embodiment, the number of second sub-pixels SPXL2 may be greater than the number of first sub-pixel SPXL1, and the number of third sub-pixels SPXL3. However, the color, type, and/or number of the first sub-pixel SPXL1, the second sub-pixel SPXL2, and the third sub-pixel SPXL3 which form each pixel PXL is not limited thereto.

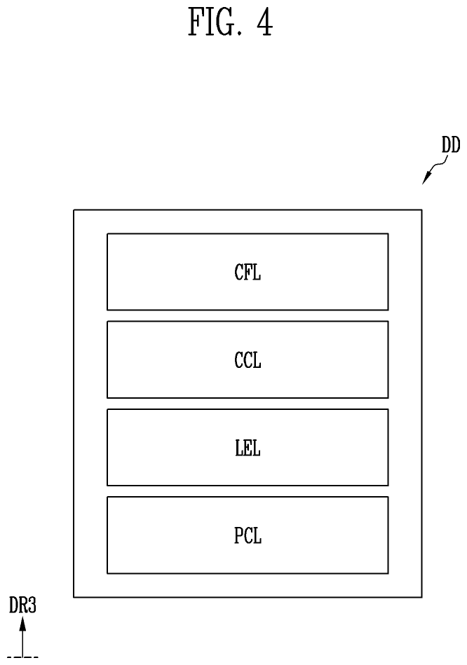

FIG. 4 is a schematic block diagram illustrating a display device in accordance with an embodiment.

Referring to FIG. 4, the display device DD may include a pixel circuit layer PCL, a light-emitting-element layer LEL, a color conversion layer CCL, and a color filter layer CFL.

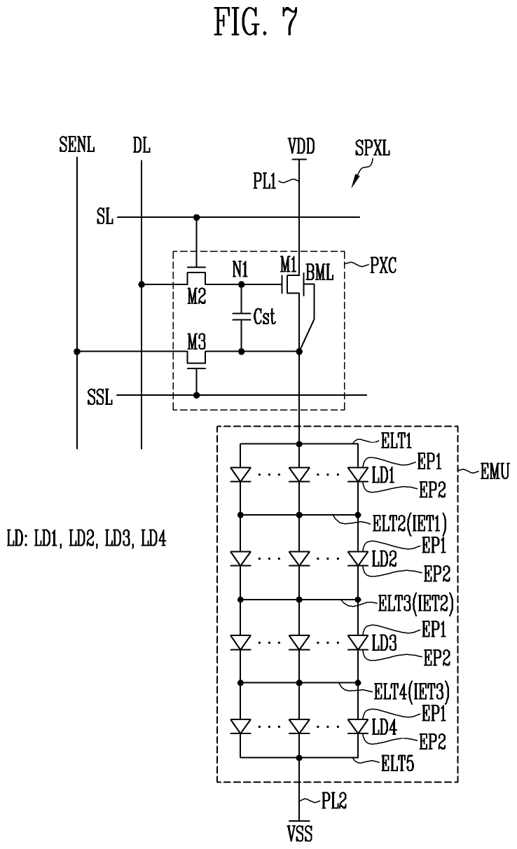

The pixel circuit layer PCL may include a pixel circuit PXC (e.g., refer to FIG. 7) configured to drive the pixel PXL. For example, the pixel circuit layer PCL may include conductive layers provided to embody the pixel circuit PXC, and insulating layers disposed on the conductive layers.

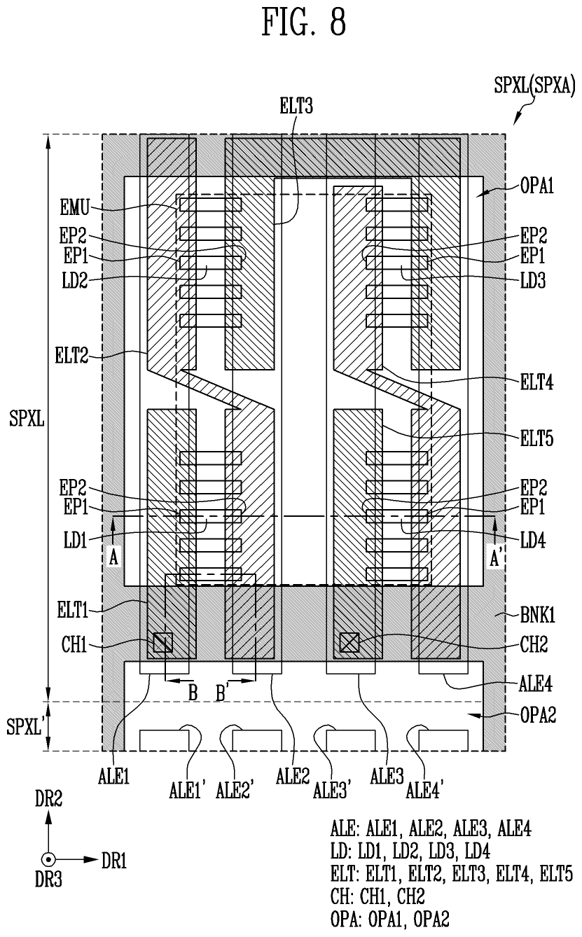

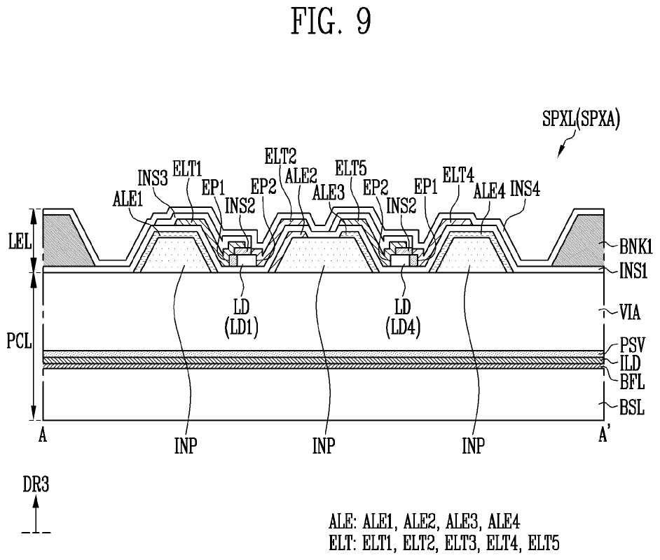

The light-emitting-element layer LEL may be disposed on the pixel circuit layer PCL. The light-emitting-element layer LEL may include a light emitting element LD. For example, the light-emitting-element layer LEL may include the light emitting element LD, conductive layers (e.g., connection electrodes ELT of FIG. 8) electrically connected to the light emitting element LD, and insulating layers (e.g., a third insulating layer INS3 of FIG. 9) disposed on the conductive layers.

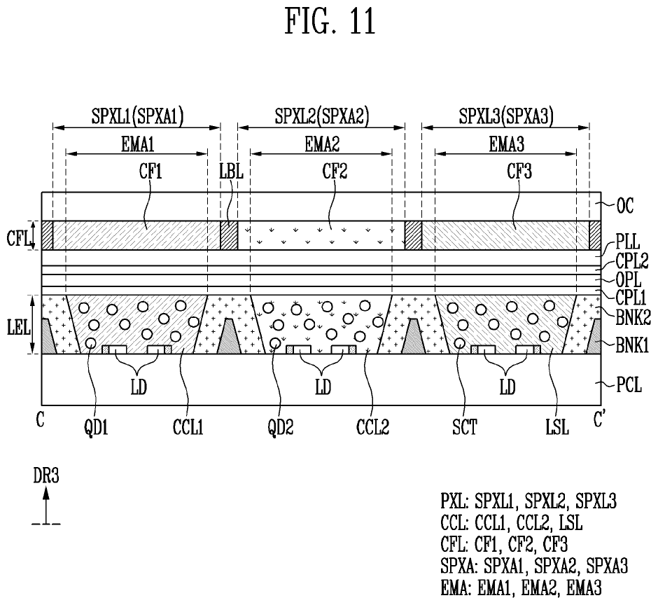

The color conversion layer CCL may be disposed on the light-emitting-element layer LEL, or the color conversion layer CCL and the light-emitting-element layer LEL may be disposed on the same layer. The color conversion layer CCL may convert at least part of the wavelength of light provided from the light emitting elements LD of the light-emitting-element layer LEL. For example, the color conversion layer CCL may include color conversion elements (e.g., first and second quantum dots QD1 and QD2 of FIG. 11).

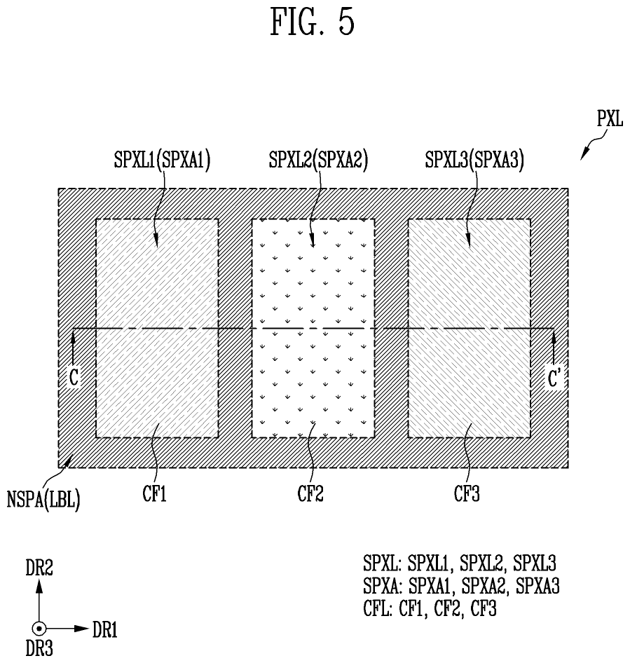

The color filter layer CFL may be disposed on the color conversion layer CCL. In an embodiment, the color filter layer CFL may be disposed between the color conversion layer CCL and the light-emitting-element layer LEL. The color filter layer CFL may include color filters CF1, CF2, and CF3 (e.g., refer to FIG. 5) each of which allows light of a color to selectively pass therethrough.

In an embodiment, the first to third sub-pixels SPXL1, SPXL2, and SPXL3 may include light emitting elements LD configured to emit light of a same color. For example, the first to third sub-pixels SPXL1, SPXL2, and SPXL3 may include light emitting elements LD configured to emit light of the third color (or blue light). Because the color conversion layer CCL is disposed on the light-emitting-element layer LEL, a full-color image may be displayed. Since the color filters CF1, CF2, and CF3 corresponding to the respective colors of the first to third sub-pixels SPXL1, SPXL2, and SPXL3 are disposed on the light-emitting-element layer LEL, a full-color image may be displayed.

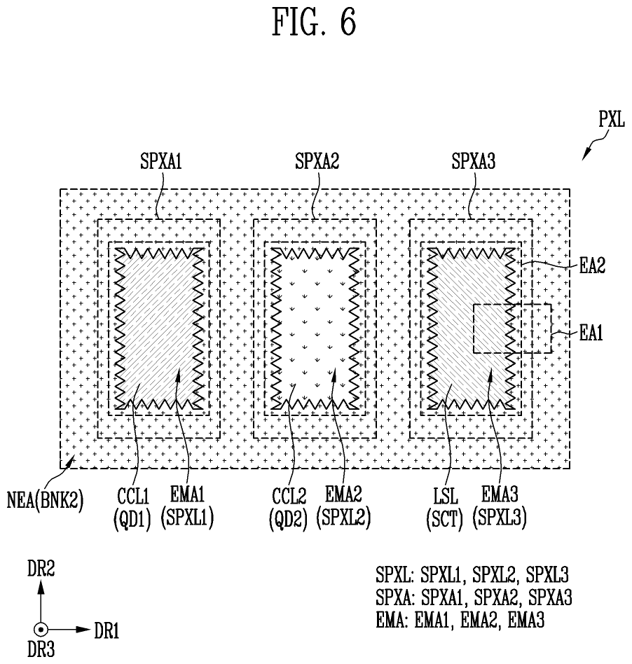

FIGS. 5 and 6 are schematic plan views illustrating a pixel in accordance with an embodiment. FIG. 5 illustrates a structure for defining the sub-pixel areas SPXA of the pixel PXL. FIG. 6 illustrates a structure for defining the emission areas EMA. For example, FIG. 5 illustrates the color filter layer CFL. FIG. 6 illustrates the color conversion layer CCL. In an embodiment, FIGS. 5 and 6 illustrate an embodiment in which the first to third sub-pixels SPXL1, SPXL2, and SPXL3 are arranged according to a certain structure. However, the disclosure is not limited thereto.

Referring to FIG. 5, the sub-pixels SPXL may include respective sub-pixel areas SPXA. The sub-pixel areas SPXA may include a first sub-pixel area SPXA1, a second sub-pixel area SPXA2, and a third sub-pixel area SPXA3. The pixel PXL may include a first sub-pixel SPXL1, a second sub-pixel SPXL2, and a third sub-pixel SPXL3 each of which emits light of a color. The first to third sub-pixels SPXL1, SPXL2, and SPXL3 may respectively correspond to the first to third sub-pixel areas SPXA1, SPXA2, and SPXA3. For example, light of different colors which is visible from the outside may be provided (or emitted) from the respective sub-pixel areas SPXA.

For example, light of a first color of the first sub-pixel SPXL1 may be emitted (or provided) from the first sub-pixel area SPXA1. Light of a second color of the second sub-pixel SPXL2 may be emitted (or provided) from the second sub-pixel area SPXA2. Light of a third color of the third sub-pixel SPXL3 may be emitted (or provided) from the third sub-pixel area SPXA3. In an embodiment, the light of the first color may be visible from the outside by a size of the first sub-pixel area SPXA1. The light of the second color may be visible from the outside by a size of the second sub-pixel area SPXA2. The light of the third color may be visible from the outside by a size of the third sub-pixel area SPXA3.

The sub-pixel areas SPXA may be defined (or determined) by a light blocking layer LBL, and the color filters CF1, CF2, and CF3 that are disposed adjacent to the light blocking layer LBL.

In an embodiment, the color filters CF1, CF2, and CF3 may be disposed in an area where the light blocking layer LBL is not disposed. In a plan view, the color filters CF1, CF2, and CF3 may not overlap the light blocking layer LBL. Hence, the pixel PXL may include a non-sub-pixel area NSPA and the sub-pixel areas SPXA. The light blocking layer LBL may be disposed in the non-sub-pixel area NSPA. The sub-pixel areas SPXA may be areas, in which the color filters CF1, CF2, and CF3 are disposed without the light blocking layer LBL.

For example, the first sub-pixel area SPXA1 may be an area where the light blocking layer LBL is not disposed, and may be an area which overlaps the first color filter CF1, in a plan view. The second sub-pixel area SPXA2 may be an area where the light blocking layer LBL is not disposed, and may be an area which overlaps the second color filter CF2, in a plan view. The third sub-pixel area SPXA3 may be an area where the light blocking layer LBL is not disposed, and may be an area which overlaps the third color filter CF3, in a plan view.

In other words, in an embodiment, ranges of the sub-pixel areas SPXA may be determined by the configuration of the color filter layer CFL regardless of the areas of the light-emitting-element layer LEL and the color conversion layer CCL. For example, the ranges of the sub-pixel areas SPXA may be adjusted by adjusting a patterning position of the light blocking layer LBL.

Referring to FIG. 6, the sub-pixels SPXL may include respective emission areas EMA. The pixel PXL may include a first emission area EMA1, a second emission area EMA2, and a third emission area EMA3 which correspond to the first to third sub-pixels SPXL1, SPXL2, and SPXL3.

For example, light may be emitted from the first emission area EMA1, and the first sub-pixel SPXL1 may emit light. Light may be emitted from the second emission area EMA2, and the second sub-pixel SPXL2 may emit light. Light may be emitted from the third emission area EMA3, and the third sub-pixel SPXL3 may emit light. In an embodiment, light emitting elements LD disposed in each sub-pixel SPXL may emit light. The emitted light may be provided to the color conversion layer CCL. The color conversion layer CCL may emit light based on the provided light (e.g., the light provided from the first to third emission areas EMA1, EMA2, and EMA3). For example, the first quantum dots QD1 of the first color conversion layer CCL1 may emit light of a first color based on light emitted from the light emitting element LD of the first sub-pixel SPXL1. The second quantum dots QD2 of the second color conversion layer CCL2 may emit light of a second color based on light emitted from the light emitting element LD of the second sub-pixel SPXL2. Scatterers SCT of a light scattering layer LSL may provide light of a third color, based on light emitted from the light emitting element LD of the third sub-pixel SPXL3.

The emission areas EMA may be defined (or determined) by a second bank BNK2 and the color conversion layer CCL that is disposed adjacent to the second bank BNK2.

In an embodiment, the color conversion layer CCL may be disposed in an area where the second bank BNK2 is not disposed. The color conversion layer CCL may not overlap the second bank BNK2, in a plan view. Hence, the pixel PXL may include non-emission areas NEA in which the second bank BNK2 is disposed, and emission areas EMA which are areas where the color conversion layer CCL is disposed without the second bank BNK2.

For example, the first emission area EMA1 may be an area where the second bank BNK2 is not disposed, and may be an area which overlaps the first color conversion layer CCL1 (or an area where the first quantum dots QD1 are disposed), in a plan view. The second emission area EMA2 may be an area where the second bank BNK2 is not disposed, and may be an area which overlaps the second color conversion layer CCL2 (or an area where the second quantum dots QD2 are disposed), in a plan view. The third emission area EMA3 may be an area where the second bank BNK2 is not disposed, and may be an area which overlaps the light scattering layer LSL (or an area where the light scattering layer LSL is disposed), in a plan view.

In other words, in an embodiment, ranges of the emission areas EMA may be determined by an area where the color conversion layer CCL is disposed. For example, the ranges of the emission areas EMA may be determined by an area where the second bank BNK2 is disposed.

In an embodiment, the ranges of the sub-pixel areas SPXA may be different from the ranges of the emission areas EMA. The sub-pixel areas SPXA may be greater than the emission areas EMA. The sub-pixel areas SPXA may have areas that expand further than the emission areas EMA. In an embodiment, the sub-pixel areas SPXA and the emission areas EMA may overlap each other, in a plan view, and at least part of each of the sub-pixel areas SPXA may not overlap a corresponding one of the emission areas EMA, in a plan view. In this case, in an embodiment, by reducing the surface areas of the emission areas EMA, the sub-pixel areas SPXA may be defined with relatively large surface areas, so that the luminance of the pixel PXL may be substantially maintained or enhanced.

In an embodiment, the second bank BNK2 may define the area where the color conversion layer CCL is disposed, and the second bank BNK2 may have a patterned shape in an area facing the area where the color conversion layer CCL is disposed. For example, FIG. 6 illustrates an embodiment where the second bank BNK2 includes a V-shaped patterned structure.

In an embodiment, the color conversion layer CCL may be disposed complementary to the patterned structure of the second bank BNK2, in a plan view. For example, the color conversion layer CCL and the second bank BNK2 may be alternately disposed in a plan view, and the color conversion layer CCL and the second bank BNK2 may not overlap in a plan view. The color conversion layer CCL may have a peripheral shape corresponding to the patterned structure of the second bank BNK2, in a plan view. For example, the peripheral shape of the color conversion layer CCL and the peripheral shape of the second bank BNK2 may be formed complementary to each other. The peripheral shape of the color conversion layer CCL and the peripheral shape of the second bank BNK2 may correspond to each other. At least part of the color conversion layer CCL may be inserted (or penetrated) into areas where at least part of the second bank BNK2 is recessed by the patterned structure thereof.

The pixel circuit PXC for driving the pixel PXL and the cross-sectional structure of the pixel PXL (or the sub-pixel SPXL) in accordance with an embodiment are described with reference to FIGS. 7 to 11. FIG. 7 is a schematic diagram of an equivalent circuit illustrating the pixel circuit PXC in accordance with an embodiment. FIGS. 8 to 11 are schematic diagrams illustrating the pixel PXL (or the sub-pixel SPXL) in accordance with an embodiment. Detailed description of the same constituent elements is omitted.

FIG. 7 is a schematic diagram of an equivalent circuit illustrating a pixel in accordance with an embodiment. In an embodiment, the sub-pixel SPXL illustrated in FIG. 7 may be any one of the first sub-pixel SPXL1, the second sub-pixel SPXL2, and the third sub-pixel SPXL3. The first sub-pixel SPXL1, the second sub-pixel SPXL2, and the third sub-pixel SPXL3 may have a substantially identical or similar structure.

Referring to FIG. 7, the pixel PXL may include an emission component EMU configured to generate light having a luminance corresponding to a data signal, and a pixel circuit PXC configured to drive the emission component EMU.

The pixel circuit PXC may be electrically connected between a first power supply VDD and the emission component EMU. The pixel circuit PXC may be electrically connected to a scan line SL and a data line DL of the corresponding pixel PXL, and control the operation of the emission component EMU in response to a scan signal and a data signal supplied from the scan line SL and the data line DL. The pixel circuit PXC may be selectively further connected (e.g., electrically connected) to a sensing signal line SSL and a sensing line SENL.

The pixel circuit PXC may include at least one transistor and at least one capacitor. For example, the pixel circuit PXC may include a first transistor M1, a second transistor M2, a third transistor M3, and a storage capacitor Cst.

The first transistor M1 may be electrically connected between the first power supply VDD and a first connection electrode ELT1. A gate electrode of the first transistor M1 may be electrically connected to the first node N1. The first transistor M1 may control driving current to be supplied to the emission component EMU in response to a voltage of the first node N1. For example, the first transistor M1 may be a driving transistor configured to control the driving current of the pixel PXL.

In an embodiment, the first transistor M1 may optionally further include a bottom conductive layer BML. The gate electrode and the bottom conductive layer BML of the first transistor M1 may overlap each other in a plan view with an insulating layer disposed therebetween. In an embodiment, the bottom conductive layer BML may be electrically connected to an electrode of the first transistor M1 (e.g., a source or drain electrode of the first transistor M1).

In case that the first transistor M1 includes the bottom conductive layer BML, a back-biasing technique (or a sync technique) may be used, the back-biasing technique being a technique of shifting a threshold voltage of the first transistor M1 in a negative direction or a positive direction by applying a back-biasing voltage to the bottom conductive layer BML of the first transistor M1 when the pixel PXL is driven. For example, a source-sync technique may be used by connecting the bottom conductive layer BML to the source electrode of the first transistor M1, so that the threshold voltage of the first transistor M1 may be shifted in the negative direction or the positive direction. In case that the bottom conductive layer BML is disposed under a semiconductor pattern that forms a channel of the first transistor M1, the bottom conductive layer BML may function as a light blocking pattern and stabilize operating characteristics of the first transistor M1. However, the function and/or application scheme of the bottom conductive layer BML is not limited thereto.

The second transistor M2 may be electrically connected between the data line DL and the first node N1. A gate electrode of the second transistor M2 may be electrically connected to the scan line SL. In case that a scan signal having a gate-on voltage (e.g., a high-level voltage) is supplied from the scan line SL, the second transistor M2 may be turned on to electrically connect the data line DL with the first node N1.

During each frame period, a data signal of the corresponding frame may be supplied to the data line DL, and the data signal may be transmitted to the first node N1 through the second transistor M2 that is turned on during a period during which the scan signal having a gate-on voltage is supplied to the scan line SL. For example, the second transistor M2 may be a switching transistor configured to transmit each data signal to the interior of the pixel PXL.

An electrode of the storage capacitor Cst may be electrically connected to the first node N1, and another electrode (or a remaining electrode) thereof may be electrically connected to a second electrode of the first transistor M1. The storage capacitor Cst may be charged with a voltage corresponding to the data signal to be supplied to the first node N1 during each frame period.

The third transistor M3 may be electrically connected between the first connection electrode ELT1 (or the second electrode of the first transistor M1) and the sensing line SENL. A gate electrode of the third transistor M3 may be electrically connected to the sensing signal line SSL. The third transistor M3 may transmit a voltage value applied to the first connection electrode ELT1, to the sensing line SENL in response to a sensing signal supplied to the sensing signal line SSL. The voltage value transmitted through the sensing line SENL may be provided to an external circuit (e.g., a timing controller). The external circuit may extract information about characteristics of each pixel PXL (e.g., a threshold voltage of the first transistor M1, etc.) based on the provided voltage value. The extracted characteristic information may be used to convert image data to compensate for a deviation in characteristics between the pixels PXL.

Although FIG. 7 illustrates the case where all of the transistors included in the pixel circuit PXC are formed of n-type transistors, the disclosure is not certainly limited thereto. For example, at least one of the first, second, and third transistors M1, M2, and M3 may be changed to a p-type transistor.

The structure and driving scheme of the pixel PXL may be changed in various ways. For instance, the pixel circuit PXC may not only be formed of the pixel circuit of the embodiment illustrated in FIG. 7 but may also be formed of a pixel circuit which may have various structures and/or be operated in various driving schemes.

For example, the pixel circuit PXC may not include the third transistor M3. The pixel circuit PXC may further include other circuit elements such as a compensation transistor configured to compensate for the threshold voltage of the first transistor M1, an initialization transistor configured to initialize the voltage of the first node N1 and/or the first connection electrode ELT1, an emission control transistor configured to control a period during which a driving current is supplied to the emission component EMU, and/or a boosting capacitor configured to boost the voltage of the first node N1.

The emission component EMU may include at least one light emitting element LD (e.g., multiple light emitting elements LD) electrically connected between the first power supply VDD and the second power supply VSS.

For example, the emission component EMU may include a first connection electrode ELT1, a fifth connection electrode ELT5, and light emitting elements LD. The first connection electrode ELT1 may be electrically connected to the first power supply VDD by the pixel circuit PXC and the first power line PL1. The fifth connection electrode ELT5 may be electrically connected to the second power supply VSS by the second power line PL2. The light emitting elements LD may be electrically connected between the first and fifth connection electrodes ELT1 and ELT5.

The first power supply VDD and the second power supply VSS may have different potentials to allow the light emitting elements LD to emit light. For example, the first power supply VDD may be set as a high-potential power supply, and the second power supply VSS may be set as a low-potential power supply.

In an embodiment, the emission component EMU may include at least one series stage. Each series stage may include a pair of electrodes (e.g., two electrodes), and at least one light emitting element LD electrically connected in a forward direction between the pair of electrodes. The number of series stages that form the emission component EMU and the number of light emitting elements LD that form each series stage are not particularly limited. For example, the numbers of light emitting elements LD that form the respective series stages may be substantially identical to each other or may be different from each other. The number of light emitting elements LD of each series stage is not particularly limited.

For example, the emission component EMU may include a first series stage including at least one first light emitting element LD1, a second series stage including at least one second light emitting element LD2, a third series stage including at least one third light emitting element LD3, and a fourth series stage including at least one fourth light emitting element LD4.

The first series stage may include a first connection electrode ELT1, a second connection electrode ELT2, and at least one first light emitting element LD1 electrically connected between the first and second connection electrodes ELT1 and ELT2. Each first light emitting element LD1 may be electrically connected in the forward direction between the first and second connection electrodes ELT1 and ELT2. For example, a first end EP1 of the first light emitting element LD1 may be electrically connected to the first connection electrode ELT1. A second end EP2 of the first light emitting element LD1 may be electrically connected to the second connection electrode ELT2.

The second series stage may include the second connection electrode ELT2, a third connection electrode ELT3, and at least one second light emitting element LD2 electrically connected between the second and third connection electrodes ELT2 and ELT3. Each second light emitting element LD2 may be electrically connected in the forward direction between the second and third connection electrodes ELT2 and ELT3. For example, a first end EP1 of the second light emitting element LD2 may be electrically connected to the second connection electrode ELT2. A second end EP2 of the second light emitting element LD2 may be electrically connected to the third connection electrode ELT3.

The third serial stage may include the third connection electrode ELT3, a fourth connection electrode ELT4, and at least one third light emitting element LD3 electrically connected between the third and fourth connection electrodes ELT3 and ELT4. Each third light emitting element LD3 may be electrically connected in the forward direction between the third and fourth connection electrodes ELT3 and ELT4. For example, a first end EP1 of the third light emitting element LD3 may be electrically connected to the third connection electrode ELT3. A second end EP2 of the third light emitting element LD3 may be electrically connected to the fourth connection electrode ELT4.

The fourth series stage may include the fourth connection electrode ELT4, the fifth connection electrode ELT5, and at least one fourth light emitting element LD4 electrically connected between the fourth and fifth connection electrodes ELT4 and ELT5. Each fourth light emitting element LD4 may be electrically connected in the forward direction between the fourth and fifth connection electrodes ELT4 and ELT5. For example, a first end EP1 of the fourth light emitting element LD4 may be electrically connected to the fourth connection electrode ELT4. A second end EP2 of the fourth light emitting element LD4 may be electrically connected to the fifth connection electrode ELT5.

The 1st electrode of the emission component EMU (e.g., the first connection electrode ELT1) may be an anode electrode of the emission component EMU. The last electrode of the emission component EMU (e.g., the fifth connection electrode ELT5) may be a cathode electrode of the emission component EMU.

Other electrodes of the emission component EMU (e.g., the second connection electrode ELT2, the third connection electrode ELT3, and/or the fourth connection electrode ELT4) each may form an intermediate electrode. For example, the second connection electrode ELT2 may form a first intermediate electrode IET1. The third connection electrode ELT3 may form a second intermediate electrode IET2. The fourth connection electrode ELT4 may form a third intermediate electrode IET3.

In case that the light emitting elements LD are electrically connected to have a series/parallel structure, power efficiency of the emission component EMU may be enhanced, compared to an emission component EMU having an equal number of light emitting elements LD which are electrically connected only in parallel to each other. In case that the light emitting elements LD are electrically connected to have a series/parallel structure, even if a short-circuit defect or the like occurs in some series stages, sufficient luminance may be expressed by the light emitting elements LD of other series stages. Thus, the probability of occurrence of a black spot defect in the pixel PXL may be reduced. However, the disclosure is not limited thereto. The emission component EMU may be formed by electrically connecting the light emitting elements LD only in series. As another example, the emission component EMU may be formed by connecting the light emitting elements LD only in parallel.

Each of the light emitting elements LD may include a first end EP1 and a second end EP2. The first end EP1 (e.g., a p-type end) may be electrically connected to the first power supply VDD via at least one electrode (e.g., the first connection electrode ELT1), the pixel circuit PXC, and/or the first power line PL1. The second end EP2 (e.g., an n-type end) may be electrically connected to the second power supply VSS via at least another electrode (e.g., the fifth connection electrode ELT5) and the second power line PL2. For example, the light emitting elements LD may be electrically connected in the forward direction between the first power supply VDD and the second power supply VSS. The light emitting elements LD electrically connected in the forward direction may form valid light sources of the emission component EMU.

When a driving current is supplied to the light emitting elements LD through the corresponding pixel circuit PXC, the light emitting elements LD may emit light having a luminance corresponding to the driving current. For example, during each frame period, the pixel circuit PXC may supply a driving current corresponding to a grayscale value (e.g., a grayscale value to be represented in the corresponding frame) to the emission component EMU. Hence, the light emitting elements LD may emit light having a luminance corresponding to the driving current, so that the emission component EMU may express the luminance corresponding to the driving current.

FIG. 8 is a schematic plan view illustrating a sub-pixel in accordance with an embodiment. FIG. 8 illustrates a sub-pixel area SPXA. The sub-pixel SPXL of FIG. 8 may be any one of the first to third sub-pixels SPXL1, SPXL2, and SPXL3, and the first to third sub-pixels SPXL1, SPXL2, and SPXL3 may have substantially identical or similar structures.

Referring to FIG. 8, the sub-pixel SPXL may include a first bank BNK1. The first bank BNK1 may form a first opening area OPA1 including an area where the light emitting elements LD are disposed, and a second opening area OPA2 including an area where the light emitting elements LD are not disposed. For example, the first bank BNK1 may protrude in a direction and may have a shape enclosing (or surrounding) the first opening area OPA1 and the second opening area OPA2. In an embodiment, the second opening area OPA2 may include an open area. For example, the open area may be included in the second opening area OPA2. The open area may refer to an area including a spacing area formed between adjacent electrodes ALE.

The electrodes ALE may be disposed in the first opening area OPA1. The electrodes ALE may extend in the second direction DR2 and be spaced apart from each other in the first direction DR1. The electrodes ALE may extend to the second opening area OPA2 from the area where the light emitting elements LD are disposed. The first to fourth electrodes ALE1, ALE2, ALE3, and ALE4 each may extend in the second direction DR2, and may be spaced apart from each other in the first direction DR1. The first to fourth electrodes ALE1, ALE2, ALE3, and ALE4 may be successively disposed.

Some of the electrodes ALE may be electrically connected to the pixel circuit PXC and/or a power line. For example, the first electrode ALE1 may be electrically connected to the pixel circuit PXC and/or the first power line PL1, and the third electrode ALE3 may be electrically connected to the second power line PL2.

In an embodiment, at least some of the electrodes ALE may be electrically connected to some of the connection electrodes ELT through any one of contact holes CH. For example, the first electrode ALE1 may be electrically connected to the first connection electrode ELT1 through a first contact hole CH1 among the contact holes CH. The third electrode ALE3 may be electrically connected to the fifth connection electrode ELT5 through a second contact hole CH2 among the contact holes CH. The contact holes CH are not particularly limited in position.

A pair of electrodes (or alignment electrodes) ALE adjacent to each other may be supplied with different signals at the step of aligning the light emitting elements LD. For example, in case that the first to fourth electrodes ALE1, ALE2, ALE3, and ALE4 are successively arranged in the first direction DR1, the first and second electrodes ALE1 and ALE2 may make a pair and be supplied with different alignment signals, and the third and fourth electrodes ALE3 and ALE4 may make a pair and be supplied with different alignment signals. Here, the alignment signals may have different waveforms, potentials, and/or phases. Accordingly, an electric field may be formed between the first and second electrodes ALE1 and ALE2, and the light emitting elements LD may be aligned between the first and second electrodes ALE1 and ALE2. Hence, an electric field may be formed between the third and fourth electrodes ALE3 and ALE3, and the light emitting elements LD may be aligned between the third and fourth electrodes ALE3 and ALE4. In an embodiment, the first to fourth electrodes ALE1, ALE2, ALE3, and ALE4 may be alignment electrodes.

In an embodiment, at least some of the electrodes ALE of the sub-pixel SPXL may be separated from at least some of electrodes ALE′ of a sub-pixel SPXL′ (e.g., an adjacent sub-pixel SPXL′) adjacent thereto with an open area disposed therebetween. For example, the first electrode ALE1 of the sub-pixel SPXL may be spaced apart from a first electrode ALE1′ (e.g., an adjacent first electrode ALE1′) of the sub-pixel SPXL′ adjacent thereto in the second direction DR2. The second electrode ALE2 of the sub-pixel SPXL may be spaced apart from a second electrode ALE2′ (e.g., an adjacent second electrode ALE2′) of the sub-pixel SPXL′ adjacent thereto in the second direction DR2. For example, the third electrode ALE3 of the sub-pixel SPXL may be spaced apart from a third electrode ALE3′ (e.g., an adjacent third electrode ALE3′) of the sub-pixel SPXL′ adjacent thereto in the second direction DR2. For example, the fourth electrode ALE4 of the sub-pixel SPXL may be spaced apart from a fourth electrode ALE4′ (e.g., an adjacent fourth electrode ALE4′) of the sub-pixel SPXL′ adjacent thereto in the second direction DR2.

In an embodiment, the first electrode ALE1 and the third electrode ALE3 may be separated from the first electrode ALE1′ and the third electrode ALE3′ of the adjacent sub-pixel SPXL′. Thus, the sub-pixel SPXL may be individually driven. However, the disclosure is not limited to the foregoing example.

The light emitting elements LD may be aligned between a pair of electrodes ALE. The light emitting elements LD each may be electrically connected between a pair of connection electrodes ELT.

The first light emitting element LD1 may be aligned between the first and second electrodes ALE1 and ALE2. The first light emitting element LD1 may be electrically connected between the first and second connection electrodes ELT1 and ELT2. For example, the first light emitting element LD1 may be aligned in first areas (e.g., lower areas or lower end areas) of the first and second electrodes ALE1 and ALE2. The first end EP1 of the first light emitting element LD1 may be electrically connected to the first connection electrode ELT1. The second end EP2 of the first light emitting element LD1 may be electrically connected to the second connection electrode ELT2.

The second light emitting element LD2 may be aligned between the first and second electrodes ALE1 and ALE2. The second light emitting element LD2 may be electrically connected between the second and third connection electrodes ELT2 and ELT3. For example, the second light emitting element LD2 may be aligned in second areas (e.g., upper areas or upper end areas) of the first and second electrodes ALE1 and ALE2. The first end EP1 of the second light emitting element LD2 may be electrically connected to the second connection electrode ELT2. The second end EP2 of the second light emitting element LD2 may be electrically connected to the third connection electrode ELT3.

The third light emitting element LD3 may be aligned between the third and fourth electrodes ALE3 and ALE4. The third light emitting element LD3 may be electrically connected between the third and fourth connection electrodes ELT3 and ELT4. For example, the third light emitting element LD3 may be aligned in second areas (e.g., upper areas or upper end areas) of the third and fourth electrodes ALE3 and ALE4. The first end EP1 of the third light emitting element LD3 may be electrically connected to the third connection electrode ELT3. The second end EP2 of the third light emitting element LD3 may be electrically connected to the fourth connection electrode ELT4.

The fourth light emitting element LD4 may be aligned between the third and fourth electrodes ALE3 and ALE4. The fourth light emitting element LD4 may be electrically connected between the fourth and fifth connection electrodes ELT4 and ELT5. For example, the fourth light emitting element LD4 may be aligned in first areas (e.g., lower areas or lower end areas) of the third and fourth electrodes ALE3 and ALE4. The first end EP1 of the fourth light emitting element LD4 may be electrically connected to the fourth connection electrode ELT4. The second end EP2 of the fourth light emitting element LD4 may be electrically connected to the fifth connection electrode ELT5.

The connection electrodes ELT each may be disposed to overlap at least one electrode ALE and/or light emitting element LD (e.g., at least one end of the light emitting element LD) in a plan view. For example, the connection electrodes ELT may be provided on the electrodes ALE and/or the light emitting elements LD in such a way that each of the connection electrodes ELT overlaps the corresponding electrodes ALE and/or the corresponding light emitting elements LD, whereby the connection electrodes ELT may be electrically connected to the light emitting elements LD.

The first connection electrode ELT1 may be disposed on the first area (e.g., the lower area or the lower end area) of the first electrode ALE1 and the first ends EP1 of the first light emitting elements LD1, and electrically connected to the first ends EP1 of the first light emitting elements LD1.

The second connection electrode ELT2 may be disposed on the first area (e.g., the lower area or the lower end area) of the second electrode ALE2 and the second ends EP2 of the first light emitting elements LD1, and electrically connected to the second ends EP2 of the first light emitting elements LD1. The second connection electrode ELT2 may be disposed on the second area (e.g., the upper area or the upper end area) of the first electrode ALE1 and the first ends EP1 of the second light emitting elements LD2, and electrically connected to the first ends EP1 of the second light emitting elements LD2. For example, the second connection electrode ELT2 may electrically connect the second ends EP2 of the first light emitting elements LD1 and the first ends EP1 of the second light emitting elements LD2 to each other. To this end, the second connection electrode ELT2 may have a bent shape. For example, the second connection electrode ELT2 may have a bent or curved structure on a boundary between an area where at least one first light emitting element LD1 is disposed and an area where at least one second light emitting element LD2 is disposed.

The third connection electrode ELT3 may be disposed on the second area (e.g., the upper area or the upper end area) of the second electrode ALE2 and the second ends EP2 of the second light emitting elements LD2, and electrically connected to the second ends EP2 of the second light emitting elements LD2. The third connection electrode ELT3 may be disposed on the second area (e.g., the upper area or the upper end area) of the fourth electrode ALE4 and the first ends EP1 of the third light emitting elements LD3, and electrically connected to the first ends EP1 of the third light emitting elements LD3. For example, the third connection electrode ELT3 may electrically connect the second ends EP2 of the second light emitting elements LD2 and the first ends EP1 of the third light emitting elements LD3 to each other. To this end, the third connection electrode ELT3 may have a bent shape. For example, the third connection electrode ELT3 may have a bent or curved structure on a boundary between an area where at least one second light emitting element LD2 is disposed and an area where at least one third light emitting element LD3 is disposed.

The fourth connection electrode ELT4 may be disposed on the second area (e.g., the upper area or the upper end area) of the third electrode ALE3 and the second ends EP2 of the third light emitting elements LD3, and thus electrically connected to the second ends EP2 of the third light emitting elements LD3. The fourth connection electrode ELT4 may be disposed on the first area (e.g., the lower area or the lower end area) of the fourth electrode ALE4 and the first ends EP1 of the fourth light emitting elements LD4, and thus electrically connected to the first ends EP1 of the fourth light emitting elements LD4. For example, the fourth connection electrode ELT4 may electrically connect the second ends EP2 of the third light emitting elements LD3 to the first ends EP1 of the fourth light emitting elements LD4. To this end, the fourth connection electrode ELT4 may have a bent shape. For example, the fourth connection electrode ELT4 may have a bent or curved structure on a boundary between an area where at least one third light emitting element LD3 is disposed and an area where at least one fourth light emitting element LD4 is disposed.

The fifth connection electrode ELT5 may be disposed on the first area (e.g., the lower area or the lower end area) of the third electrode ALE3 and the second ends EP2 of the fourth light emitting elements LD4, and electrically connected to the second ends EP2 of the fourth light emitting elements LD4.

Thus, the light emitting elements LD aligned between the electrodes ALE may be connected in a desired form by using the connection electrodes ELT. For example, the first light emitting elements LD1, the second light emitting elements LD2, the third light emitting elements LD3, and the fourth light emitting elements LD4 may be successively connected (or electrically connected) in series by using the connection electrodes ELT.

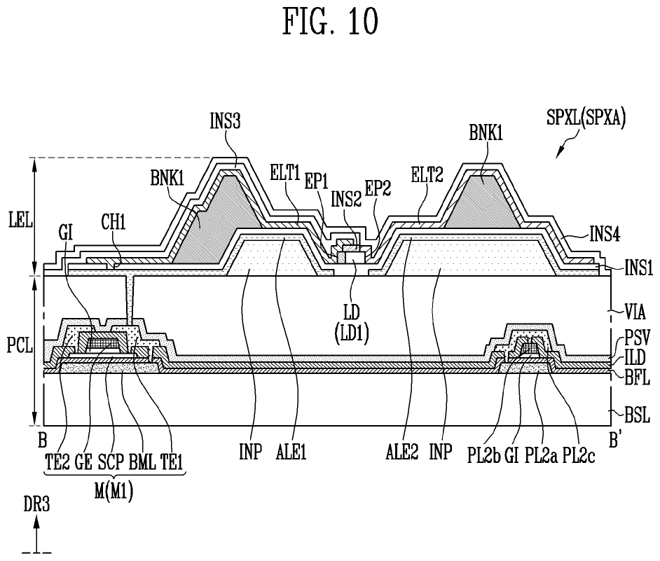

Hereinafter, a cross-sectional structure of each pixel PXL (or each sub-pixel SPXL) is described in detail based on the light emitting element LD, with reference to FIGS. 9 and 10. FIGS. 9 and 10 illustrate a pixel circuit layer PCL and a light-emitting-element layer LEL of the pixel PXL. FIG. 10 illustrates a first transistor M1 of various circuit elements that form the pixel circuit PXC. In case that the first to third transistors M1, M2, and M3 are not separately designated, the term “transistor M” may be collectively used. The structures of the transistors M and/or positions in layers thereof are not limited to those of the embodiment shown in FIG. 10 and may be changed in various ways depending on embodiments. FIG. 9 is a schematic sectional view taken along line A-A′ of FIG. 8. FIG. 10 is a schematic sectional view taken along line B-B′ of FIG. 8.

Referring to FIGS. 9 and 10, the pixel circuit layer PCL and the light-emitting-element layer LEL for the pixels PXL (or the sub-pixels SPXL) in accordance with an embodiment may include circuit elements and various lines electrically connected to the circuit elements. The circuit elements may include transistors M disposed on the base layer BSL. The light-emitting-element layer LEL may include the electrodes ALE, the light emitting elements LD, and/or the connection electrodes ELT and be disposed on the pixel circuit layer PCL.

The base layer BSL may be a rigid or flexible substrate or film. For example, the base layer BSL may be a rigid substrate made of glass or reinforced glass, a flexible substrate (or a thin film) formed of plastic or metal, or at least one insulating layer. The material and/or properties of the base layer BSL are not particularly limited. In an embodiment, the base layer BSL may be substantially transparent. Here, the words “substantially transparent” may mean that light may pass through the substrate SUB at a certain transmissivity or more. In an embodiment, the base layer BSL may be translucent or opaque. In some embodiments, the base layer BSL may include reflective material.

The bottom conductive layer BML and a first power conductive layer PL2a may be disposed on the base layer BSL. The bottom conductive layer BML and the first power conductive layer PL2a may be disposed on a same layer. For example, the bottom conductive layer BML and the first power conductive layer PL2a may be simultaneously formed through a same process, but the disclosure is not limited thereto. The first power conductive layer PL2a may form the second power line PL2 described with reference to FIG. 7 or the like.

The bottom conductive layer BML and the first power conductive layer PL2a each may have a single layer structure or a multilayer structure that includes (or is formed of) at least one of molybdenum (Mo), copper (Cu), aluminum (Al), chrome (Cr), gold (Au), titanium (Ti), nickel (Ni), neodymium (Nd), indium (In), tin (Sn), an oxide thereof, and an alloy thereof.

A buffer layer BFL may be disposed on the bottom conductive layer BML and the first power conductive layer PL2a. The buffer layer BFL may prevent impurities from diffusing into a circuit element. The buffer layer BFL may be formed of a single layer, or may be formed of multiple layers having at least two or more layers. In case that the buffer layer BFL has a multilayer structure, respective layers of the multilayer structure may be formed of a same material or different materials.

A semiconductor pattern SCP may be disposed on the buffer layer BFL. For example, the semiconductor pattern SCP may include a first area which contacts a first transistor electrode TE1, a second area which contacts a second transistor electrode TE2, and a channel area disposed between the first and second areas. In an embodiment, one of the first and second areas may be a source area, and another of the first and second areas may be a drain area.

In an embodiment, the semiconductor pattern SCP may be formed of polysilicon, amorphous silicon, an oxide semiconductor, or the like. The channel area of the semiconductor pattern SCP may be an intrinsic semiconductor, which is an undoped semiconductor pattern. Each of the first and second areas of the semiconductor pattern SCP may be a semiconductor doped with a dopant.

A gate insulating layer GI may be disposed on the buffer layer BFL and the semiconductor pattern SCP. For example, the gate insulating layer GI may be disposed between the semiconductor pattern SCP and the gate electrode GE. The gate insulating layer GI may be disposed between the buffer layer BFL and a second power conductive layer PL2b. The gate insulating layer GI may be formed of a single layer or multiple layers, and include various inorganic materials including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The gate electrode GE of the transistor M and the second power conductive layer PL2b may be disposed on the gate insulating layer GI. The gate electrode GE and the second power conductive layer PL2b may be disposed on a same layer. For example, the gate electrode GE and the second power conductive layer PL2b may be simultaneously formed through a same process, but the disclosure is not limited thereto. The gate electrode GE may be disposed on the gate insulating layer GI and overlap the semiconductor pattern SCP in a third direction DR3. The second power conductive layer PL2b may be disposed on the gate insulating layer GI and overlap the first power conductive layer PL2a in the third direction DR3. The second power conductive layer PL2b and the first power conductive layer PL2a may form the second power line PL2 described with reference to FIG. 7 or the like.

The gate electrode GE and the second power conductive layer PL2b each may have a single layer or multilayer structure including (or formed of) at least one of molybdenum (Mo), copper (Cu), aluminum (Al), chrome (Cr), gold (Au), titanium (Ti), nickel (Ni), neodymium (Nd), indium (In), tin (Sn), an oxide thereof, and an alloy thereof.

An interlayer insulating layer ILD may be disposed on the gate electrode GE and the second power conductive layer PL2b. For example, the interlayer insulating layer ILD may be disposed between the gate electrode GE and the first and second transistor electrodes TE1 and TE2. The interlayer insulating layer ILD may be disposed between the second power conductive layer PL2b and a third power conductive layer PL2c.

The interlayer insulating layer ILD may be formed of a single layer or multiple layers, and include various inorganic materials including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The first and second transistor electrodes TE1 and TE2 of the transistor M and the third power conductive layer PL2c may be disposed on the interlayer insulating layer ILD. The first and second transistor electrodes TE1 and TE2 and the third power conductive layer PL2c may be disposed on a same layer. For example, the first and second transistor electrodes TE1 and TE2 and the third power conductive layer PL2c may be simultaneously formed through a same process, but the disclosure is not limited thereto.

The first and second transistor electrodes TE1 and TE2 may overlap the semiconductor pattern SCP in the third direction DR3. The first and second transistor electrodes TE1 and TE2 may be electrically connected to the semiconductor pattern SCP. For example, the first transistor electrode TE1 may be electrically connected with the first area of the semiconductor pattern SCP through a contact hole passing through the interlayer insulating layer ILD. The first transistor electrode TE1 may be electrically connected with the bottom conductive layer BML through a contact hole passing through the interlayer insulating layer ILD and the buffer layer BFL. The second transistor electrode TE2 may be electrically connected with the second area of the semiconductor pattern SCP through a contact hole passing through the interlayer insulating layer ILD. In an embodiment, any one of the first and second transistor electrodes TE1 and TE2 may be a source electrode, and the other one may be a drain electrode.

The third power conductive layer PL2c may be disposed to overlap the first power conductive layer PL2a and/or the second power conductive layer PL2b in the third direction DR3. The third power conductive layer PL2c may be electrically connected to the first power conductive layer PL2a and/or the second power conductive layer PL2b. For example, the third power conductive layer PL2c may be electrically connected to the first power conductive layer PL2a through a contact hole passing through the interlayer insulating layer ILD and the buffer layer BFL. The third power conductive layer PL2c may be electrically connected to the second power conductive layer PL2b through a contact hole passing through the interlayer insulating layer ILD. The third power conductive layer PL2c, the first power conductive layer PL2a, and/or the second power conductive layer PL2b may form the second power line PL2 described with reference to FIG. 7 or the like.

The first and second transistor electrodes TE1 and TE2 and the third power conductive layer PL2c each may have a single layer structure or a multilayer structure that includes (or is formed of) at least one of molybdenum (Mo), copper (Cu), aluminum (Al), chrome (Cr), gold (Au), titanium (Ti), nickel (Ni), neodymium (Nd), indium (In), tin (Sn), an oxide thereof, and an alloy thereof.

A passivation layer PSV may be disposed on the first and second transistor electrodes TE1 and TE2 and the third power conductive layer PL2c. The passivation layer PSV may be formed of a single layer or multiple layers, and include various inorganic materials including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

A via layer VIA may be disposed on the passivation layer PSV. The via layer VIA may be formed of organic material for planarizing a stepped structure formed thereunder. For example, the via layer VIA may include at least one organic material of acrylic resin, epoxy resin, phenolic resin, polyamide resin, polyimide resin, polyester resin, polyphenylene sulfide resin, and benzocyclobutene (BCB). However, the disclosure is not limited thereto. The via layer VIA may include various inorganic materials including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

Insulating patterns INP of the light-emitting-element layer LEL may be disposed on the via layer VIA of the pixel circuit layer PCL. Depending on embodiments, the insulating patterns INP may have various shapes. In an embodiment, the insulating patterns INP each may have a shape protruding from the base layer BSL in the third direction DR3. The insulating patterns INP each may have an inclined surface which is inclined at an angle (e.g., a certain or selectable angle) with respect to the base layer BSL. However, the disclosure is not limited thereto. The including patterns INP each may have a sidewall having a curved or stepped shape. For example, the insulating patterns INP each may have a cross-sectional shape such as a semi-circular or semi-elliptical shape.

In an embodiment, the via layer VIA may be referred to as a lower insulating layer.

The electrodes ALE and the first insulating layer INS1 that are disposed on the insulating patterns INP may have shapes corresponding to those of the insulating patterns INP. For example, the electrodes ALE that are disposed on the insulating patterns INP may include inclined surfaces or curved surfaces having shapes corresponding to that of the insulating patterns INP. Hence, the insulating patterns INP and the electrodes ALE provided thereon may function as reflectors for guiding light emitted from the light emitting elements LD in a frontal direction (e.g., the third direction DR3) of the pixel PXL, and the light output efficiency of the display panel PNL may be enhanced.

The insulating patterns INP may include at least one organic material and/or inorganic material. For example, the insulating patterns INP may include at least one organic material of acrylic resin, epoxy resin, phenolic resin, polyamide resin, polyimide resin, polyester resin, polyphenylene sulfide resin, and benzocyclobutene (BCB). However, the disclosure is not limited thereto. The insulating patterns INP may include various inorganic materials including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The electrodes ALE may be disposed on the via layer VIA and the insulating patterns INP. The electrodes ALE may be disposed at positions spaced apart from each other in the pixel PXL. The electrodes ALE may be disposed on a same layer. For example, the electrodes ALE may be simultaneously formed through a same process, but the disclosure is not limited thereto.

The electrodes ALE may be supplied with alignment signals at the step of aligning the light emitting elements LD. Therefore, an electric field may be formed between the electrodes ALE, and the light emitting elements LD that are provided in each of the pixels PXL may be aligned between the electrodes ALE.

The electrodes ALE may include at least one conductive material. For example, the electrodes ALE may include at least one conductive material among at least one metal of various metal materials including silver (Ag), magnesium (Mg), aluminum (Al), platinum (Pt), palladium (Pd), gold (Au), nickel (Ni), neodymium (Nd), iridium (Ir), chrome (Cr), titanium (Ti), molybdenum (Mo), copper (Cu), etc., or an alloy thereof, conductive oxide such as indium tin oxide (ITO), indium zinc oxide (IZO), indium tin zinc oxide (ITZO), aluminum zinc oxide (AZO), gallium zinc oxide (GZO), zinc tin oxide (ZTO), or gallium tin oxide (GTO), and a conductive polymer such as PEDOT, but the disclosure is not limited thereto.

The first insulating layer INS1 may be disposed on the electrodes ALE. The first insulating layer INS1 may be formed of a single layer or multiple layers, and include various inorganic materials including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The first bank BNK1 may be disposed on the first insulating layer INS1. The first bank BNK1 may form, at the step of supplying the light emitting elements LD to each pixel PXL, a dam structure for defining an emission area to which the light emitting elements LD are to be supplied. The first bank BNK1 may protrude in the thickness direction of the base layer BSL (e.g., in the third direction DR3). For example, a desired kind and/or amount of light-emitting-element ink may be supplied to the area defined by the first bank BNK1.

The first bank BNK1 may include organic material such as acrylic resin, epoxy resin, phenolic resin, polyamide resin, polyimide resin, polyester resin, polyphenylene sulfide resin, or benzocyclobutene (BCB). However, the disclosure is not limited thereto. The first bank BNK1 may include various inorganic materials including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

In an embodiment, the first bank BNK1 may include at least one light shielding and/or reflective material. Therefore, a light leakage between adjacent pixels PXL may be prevented from being caused. For example, the first bank BNK1 may include at least one black matrix material and/or color filter material. For instance, the bank BNK may be formed of a black opaque pattern which may block transmission of light. In an embodiment, a reflective layer (not illustrated) or the like may be formed on a surface (e.g., a sidewall) of the first bank BNK1 and increase the light efficiency of each pixel PXL.

The light emitting elements LD may be disposed on the first insulating layer INS1. The light emitting elements LD may be adjacent to (or disposed in an area enclosed by) the first bank BNK1. The light emitting elements LD may be disposed on the first insulating layer INS1 between the electrodes ALE. The light emitting elements LD may be prepared in a diffused form in the light emitting element ink, and supplied to each of the pixels PXL by an inkjet printing scheme or the like. For example, the light emitting elements LD may be diffused in a volatile solvent and supplied to each of the pixels PXL. Thereafter, in case that the alignment signals are supplied to the electrodes ALE, an electric field may be formed between the electrodes ALE so that the light emitting elements LD may be aligned between the electrodes ALE. After the light emitting elements LD have been aligned, the solvent may be removed by a volatilization scheme or other schemes. In this way, the light emitting elements LD may be reliably disposed between the electrodes ALE.

A second insulating layer INS2 may be disposed on the light emitting elements LD. For example, the second insulating layer INS2 may be partially provided on the light emitting elements LD, and the first and second ends EP1 and EP2 of the light emitting elements LD may be exposed from the second insulating layer INS2. In case that the second insulating layer INS2 is formed on the light emitting elements LD after the alignment of the light emitting elements LD has been completed, the light emitting elements LD may be prevented from being removed from the aligned positions.

In an embodiment, a portion of the second insulating layer INS2 may be disposed on the first insulating layer INS1 and/or the first bank BNK1. For example, the second insulating layer INS2 may allow at least part of the light emitting element LD to be exposed and may be disposed in at least a partial area of the pixel PXL (or the sub-pixel SPXL).

The second insulating layer INS2 may be formed of a single layer or multiple layers, and include various inorganic materials including at least one of silicon oxide (SiOₓ), silicon nitride (SiNₓ), silicon oxynitride (SiOₓ N y), aluminum nitride (AlNₓ), aluminum oxide (AlOₓ), zirconium oxide (ZrOₓ), hafnium oxide (HfOₓ), and titanium oxide (TiOₓ).

The connection electrodes ELT may be disposed on the first and second ends EP1 and EP2 of the light emitting elements LD that are exposed from the second insulating layer INS2. The connection electrodes ELT may be disposed on a same layer. For example, the connection electrodes ELT may be formed of a same conductive layer. The connection electrodes ELT may be simultaneously formed through a same process. However, the disclosure is not limited to the foregoing example. For example, the connection electrodes ELT may be formed through different processes. For example, the first connection electrode ELT1, the third connection electrode ELT3, and the fifth connection electrode ELT5 may be patterned and, thereafter, the second connection electrode ELT2 and the fourth connection electrode ELT4 may be patterned.

The first connection electrode ELT1 may be disposed (e.g., directly disposed) on the first ends EP1 of the first light emitting elements LD1 and contact the first ends EP1 of the first light emitting elements LD1.

The second connection electrode ELT2 may be disposed (e.g., directly disposed) on the second ends EP2 of the first light emitting elements LD1 and contact the second ends EP2 of the first light emitting elements LD1. The second connection electrode ELT2 may be disposed (e.g., directly disposed) on the first ends EP1 of the second light emitting elements LD2 and contact the first ends EP1 of the second light emitting elements LD2. For example, the second connection electrode ELT2 may electrically connect the second ends EP2 of the first light emitting elements LD1 with the first ends EP1 of the second light emitting elements LD2.

The third connection electrode ELT3 may be disposed (e.g., directly disposed) on the second ends EP2 of the second light emitting elements LD2 and contact the second ends EP2 of the second light emitting elements LD2. The third connection electrode ELT3 may be disposed (e.g., directly disposed) on the first ends EP1 of the third light emitting elements LD3 and contact the first ends EP1 of the third light emitting elements LD3. For example, the third connection electrode ELT3 may electrically connect the second ends EP2 of the second light emitting elements LD2 with the first ends EP1 of the third light emitting elements LD3.

The fourth connection electrode ELT4 may be disposed (e.g., directly disposed) on the second ends EP2 of the third light emitting elements LD3 and contact the second ends EP2 of the third light emitting elements LD3. The fourth connection electrode ELT4 may be disposed (e.g., directly disposed) on the first ends EP1 of the fourth light emitting elements LD4 and contact the first ends EP1 of the fourth light emitting elements LD4. For example, the fourth connection electrode ELT4 may electrically connect the second ends EP2 of the third light emitting elements LD3 with the first ends EP1 of the fourth light emitting elements LD4.

The fifth connection electrode ELT5 may be disposed (e.g., directly disposed) on the second ends EP2 of the fourth light emitting elements LD4 and contact the second ends EP2 of the fourth light emitting elements LD4.

The connection electrodes ELT may be formed of various transparent conductive materials. For example, the connection electrodes ELT may include various transparent conductive materials including at least one of indium tin oxide (ITO), indium zinc oxide (IZO), indium tin zinc oxide (ITZO), aluminum zinc oxide (AZO), gallium zinc oxide (GZO), zinc tin oxide (ZTO), and gallium tin oxide (GTO), and may be substantially transparent or translucent to provide satisfactory transmittance. Hence, light emitted from the first and second ends EP1 and EP2 of the light emitting elements LD may pass through the connection electrodes ELT and be emitted out of the display device DD.

In an embodiment, the first connection electrode ELT1, the third connection electrode ELT3, and the fifth connection electrode ELT5 may be formed through a process different from that of the second connection electrode ELT2 and the fourth connection electrode ELT4. However, the disclosure is not limited thereto. For example, the first to fifth connection electrodes ELT1 to ELT5 may be formed through a same process.

In an embodiment, the third insulating layer INS3 may be disposed between the first connection electrode ELT1 and the second connection electrode ELT2 and between the fifth connection electrode ELT5 and the fourth connection electrode ELT4. The third insulating layer INS3 may prevent a short-circuit defect between adjacent connection electrodes ELT from occurring. In an embodiment, a fourth insulating layer INS4 may be disposed in a peripheral portion of the light-emitting-element layer LEL. The fourth insulating layer INS4 may protect the light-emitting-element layer LEL from external influence.

In an embodiment, the third insulating layer INS3 and the fourth insulating layer INS4 each may be formed of a single layer or multiple layers, and may include various inorganic materials including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The cross-sectional structure of the pixel PXL including the color conversion layer CCL and the color filter layer CFL is described with reference to FIG. 11. FIG. 11 is a schematic sectional view illustrating the first to third sub-pixels in accordance with an embodiment. FIG. 11 is a schematic sectional view taken along line C-C′ of FIG. 5.

FIG. 11 illustrates the second bank BNK2, the color conversion layer CCL, an optical layer OPL, the color filter layer CFL, and the like. For the convenience of description, in FIG. 11, the light emitting elements LD and the first bank BNK1 are illustrated, and some of detailed configurations of the pixel circuit layer PCL and the light-emitting-element layer LEL of FIGS. 9 and 10 are omitted.

Referring to FIG. 11, the second bank BNK2 may be disposed between the first to third sub-pixels SPXL1, SPXL2, and SPXL3. For example, the second bank BNK2 may be disposed on boundaries between adjacent ones of the first to third sub-pixels SPXL1, SPXL2, and XPXL3. The second bank BNK2 may include an opening which overlaps each of the first to third sub-pixels SPXL1, SPXL2, and SPXL3 in a plan view. The second bank BNK2 may be disposed on the first bank BNK1. The opening of the second bank BNK2 may provide a space in which the color conversion layer CCL may be provided. For example, the color conversion layer CCL of a kind and/or amount (e.g., a desired or selectable kind and/or amount) may be supplied to the space defined by the opening of the second bank BNK2.

In an embodiment, the emission areas EMA may be defined in an area where the second bank BNK2 is not disposed. As described above, the first quantum dots QD1, the second quantum dots QD2, and the scatterers SCT may be disposed in an area enclosed by the second bank BNK2 (or the area where the second bank BNK2 is not disposed).

The second bank BNK2 may include organic material such as acrylic resin, epoxy resin, phenolic resin, polyamide resin, polyimide resin, polyester resin, polyphenylene sulfide resin, or benzocyclobutene (BCB). However, the disclosure is not limited thereto. The second bank BNK2 may include various inorganic materials including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

In an embodiment, the second bank BNK2 may include at least one light shielding and/or reflective material. Therefore, a light leakage between adjacent pixels PXL may be prevented from being caused. For example, the second bank BNK2 may include a black pigment, but the disclosure is not limited thereto.

The color conversion layer CCL may be disposed on the light emitting elements LD in the opening of the second bank BNK2. The color conversion layer CCL may include a first color conversion layer CCL1 disposed in the first sub-pixel SPXL1, a second color conversion layer CCL2 disposed in the second sub-pixel SPXL2, and a light scattering layer LSL disposed in the third sub-pixel SPXL3.

The first color conversion layer CCL1 may include first color conversion particles for converting light of the third color emitted from the light emitting element LD to light of the first color. For example, the first color conversion layer CCL1 may include first quantum dots QD1 which are dispersed in a matrix material such as base resin.

In an embodiment, in case that the light emitting element LD is a blue light emitting element configured to emit blue light and the first sub-pixel SPXL1 is a red pixel, the first color conversion layer CCL1 may include the first quantum dots QD1 which may convert blue light emitted from the blue light emitting element to red light. The first quantum dots QD1 may absorb blue light, shift the wavelength thereof according to an energy transition, and emit red light. In case that the first sub-pixel SPXL1 is one of pixels of other colors, the first color conversion layer CCL1 may include the first quantum dots QD1 corresponding to the color of the first sub-pixel SPXL1.

The second color conversion layer CCL2 may include second color conversion particles for converting light of the third color emitted from the light emitting element LD to light of the second color. For example, the second color conversion layer CCL2 may include second quantum dots QD2 which are dispersed in a matrix material such as base resin.

In an embodiment, in case that the light emitting element LD is a blue light emitting element configured to emit blue light and the second sub-pixel SPXL2 is a green pixel, the second color conversion layer CCL2 may include the second quantum dots QD2 which may convert blue light emitted from the blue light emitting element to green light. The second quantum dots QD2 may absorb blue light, shift the wavelength thereof according to an energy transition, and emit green light. In case that the second sub-pixel SPXL2 is one of pixels of other colors, the second color conversion layer CCL2 may include the second quantum dots QD2 corresponding to the color (e.g., the other colors) of the second sub-pixel SPXL2.

In an embodiment, as blue light having a relatively short wavelength in a visible ray area is incident on each of the first quantum dots QD1 and the second quantum dots QD2, absorption coefficients of the first quantum dot QD1 and the second quantum dot QD2 may be increased. Therefore, the efficiency of light emitted from the first sub-pixel SPXL1 and the second sub-pixel SPXL2 may be enhanced, and satisfactory color reproducibility may be secured. Since the emission circuit EMU for the first to third sub-pixels SPXL1, SPXL2, and SPXL3 is formed of light emitting elements LD (e.g., blue light emitting elements) configured to emit light of a same color, the efficiency of fabricating the display device may be enhanced.

The light scattering layer LSL may be provided to efficiently use light of the third color (or blue light) emitted from the light emitting element LD. For example, in case that the light emitting element LD is a blue light emitting element configured to emit blue light and the third sub-pixel SPXL3 is a blue pixel, the light scattering layer LSL may include at least one type of light scatterer SCT to efficiently use light emitted from the light emitting element LD. For example, the light scatterers SCT of the light scattering layer LSL may include at least one of barium sulfate (BaSO4), calcium carbonate (CaCO3), titanium oxide (TiO2), silicon oxide (SiO2), aluminum oxide (Al2O3), and zinc oxide (ZnO). The light scatterers SCT may not only be provided in the third sub-pixel SPXL3, but may also be selectively included in the first conversion layer CCL1 or the second color conversion layer CCL2. In an embodiment, the light scatterers SCT may be omitted, and the light scattering layer LSL may be formed of transparent polymer.

A first capping layer CPL1 may be disposed on the color conversion layer CCL. The first capping layer CPL1 may be provided over the first to third sub-pixels SPXL1, SPXL2, and SPXL3. The first capping layer CPL1 may cover the color conversion layer CCL. The first capping layer CPL1 may prevent the color conversion layer CCL from being damaged or contaminated by permeation of external impurities such as water or air.

The first capping layer CPL1 may be an inorganic layer, and include (or be formed of) at least one of silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), and silicon oxynitride (SiOₓN_{y}).

The optical layer OPL may be disposed on the first capping layer CPL1. The optical layer OPL may function to recycle light provided from the color conversion layer CCL by total reflection and enhance light extraction efficiency. Hence, the optical layer OPL may have a relatively low refractive index compared to that of the color conversion layer CCL. For example, the refractive index of the color conversion layer CCL may be in a range of about 1.6 to about 2.0, and the refractive index of the optical layer OPL may be in a range of about 1.1 to about 1.3.

A second capping layer CPL2 may be disposed on the optical layer OPL. The second capping layer CPL2 may be provided over the first to third sub-pixels SPXL1, SPXL2, and SPXL3. The second capping layer CPL2 may cover the optical layer OPL. The second capping layer CPL2 may prevent the optical layer OPL from being damaged or contaminated by permeation of external impurities such as water or air.

The second capping layer CPL2 may be an inorganic layer, and may be formed of (or may include) at least one of silicon nitride (SiNₓ), aluminum nitride (AlNₓ), titanium nitride (TiN x), silicon oxide (SiOₓ), aluminum oxide (AlOₓ), titanium oxide (TiOₓ), silicon oxycarbide (SiOₓ C_{y}), and silicon oxynitride (SiOₓN_{y}).

A planarization layer PLL may be disposed on the second capping layer CPL2. The planarization layer PLL may be provided over the first to third sub-pixels SPXL1, SPXL2, and SPXL3.

The planarization layer PLL may include organic material such as acrylic resin, epoxy resin, phenolic resin, polyamide resin, polyimide resin, polyester resin, polyphenylene sulfide resin, or benzocyclobutene (BCB). However, the disclosure is not limited thereto. The planarization layer PLL may include various inorganic materials including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The color filter layer CFL may be disposed on the planarization layer PLL. The color filter layer CFL may include color filters CF1, CF2, and CF3 corresponding to the colors of the respective pixels PXL. The color filter layer CFL may include a first color filter CF1, a second color filter CF2, and a third color filter CF3. The first color filter CF1 may be disposed in the first sub-pixel SPXL1 and configured to allow light emitted from the first sub-pixel SPXL1 to selectively pass therethrough. The second color filter CF2 may be disposed in the second sub-pixel SPXL2 and configured to allow light emitted from the second sub-pixel SPXL2 to selectively pass therethrough. The third color filter CF3 may be disposed in the third sub-pixel SPXL3 and configured to allow light emitted from the third sub-pixel SPXL3 to selectively pass therethrough.

In an embodiment, the first color filter CF1, the second color filter CF2, and the third color filter CF3 may be respectively a red color filter, a green color filter, and a blue color filter, but the disclosure is not limited thereto.

The first color filter CF1 may overlap the first color conversion layer CCL1 in the third direction DR3. The first color filter CF1 may include color filter material for allowing light of the first color (or red light) to selectively pass therethrough. For example, in case that the first sub-pixel SPXL1 is a red pixel, the first color filter CF1 may include red color filter material.

The second color filter CF2 may overlap the second color conversion layer CCL2 in the third direction DR3. The second color filter CF2 may include color filter material for allowing light of the second color (or green light) to selectively pass therethrough. For example, in case that the second sub-pixel SPXL2 is a green pixel, the second color filter CF2 may include green color filter material.

The third color filter CF3 may overlap the light scattering layer LSL in the third direction DR3. The third color filter CF3 may include color filter material for allowing light of the third color (or blue light) to selectively pass therethrough. For example, in case that the third sub-pixel SPXL3 is a blue pixel, the third color filter CF3 may include blue color filter material.

A light blocking layer LBL may be disposed between the first to third color filters CF1, CF2, and CF3. In case that the light blocking layer LBL is formed between the first to third color filters CF1, CF2, and CF3, a color mixing defect which is visible from a front surface or side surface of the display device DD may be prevented from occurring. The material of the light blocking layer LBL is not particularly limited and may include various light blocking materials (e.g., a black matrix). For example, the light blocking layer LBL may be embodied by stacking the first to third color filters CF1, CF2, and CF3. In an embodiment, the sub-pixel areas SPXA may be formed wider than the respective emission areas EMA corresponding thereto. For example, the first sub-pixel area SPXA1 may be formed wider than the first emission area EMA1. The first sub-pixel area SPXA1 may cover an entire area of the first emission area EMA1. The second sub-pixel area SPXA2 may be formed wider than the second emission area EMA2. The second sub-pixel area SPXA2 may cover an entire area of the second emission area EMA2. The third sub-pixel area SPXA3 may be formed wider than the third emission area EMA3. The third sub-pixel area SPXA3 may cover an entire area of the third emission area EMA3. In an embodiment, the second bank BNK2 may be formed wider than the light blocking layer LBL, in a plan view. For example, the second bank BNK2 may cover an entire area of the light blocking layer LBL, in a plan view. The second bank BNK2 may overlap the color filters CF1, CF2, and CF3, in a plan view.

An overcoat layer OC may be disposed on the color filter layer CFL. The overcoat layer OC may be provided over the first to third sub-pixels SPXL1, SPXL2, and SPXL3. The overcoat layer OC may cover a lower component including the color filter layer CFL. The overcoat layer OC may prevent water or air from permeating the lower component. The overcoat layer OC may protect the lower component from foreign material such as dust.

The overcoat layer OC may include organic material such as acrylic resin, epoxy resin, phenolic resin, polyamide resin, polyimide resin, polyester resin, polyphenylene sulfide resin, or benzocyclobutene (BCB). However, the disclosure is not limited thereto. The overcoat layer OC may include various inorganic materials including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

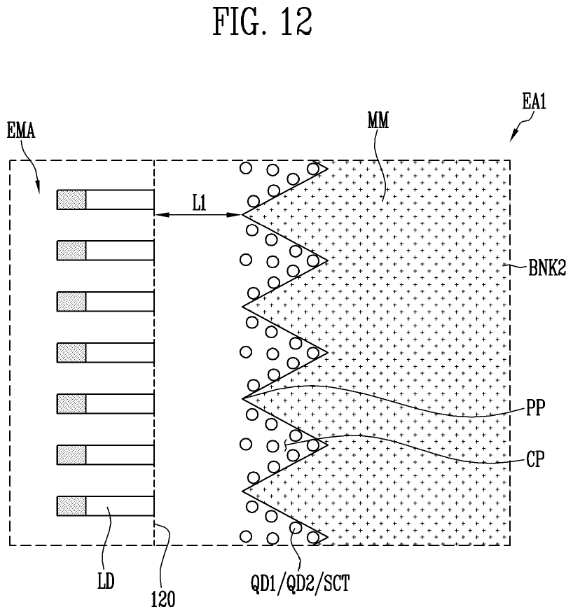

Hereinafter, a peripheral structure of the second bank BNK2 for defining the emission areas EMA in accordance with an embodiment is described with reference to FIGS. 12 to 18. Repetitive description will be simplified or omitted.

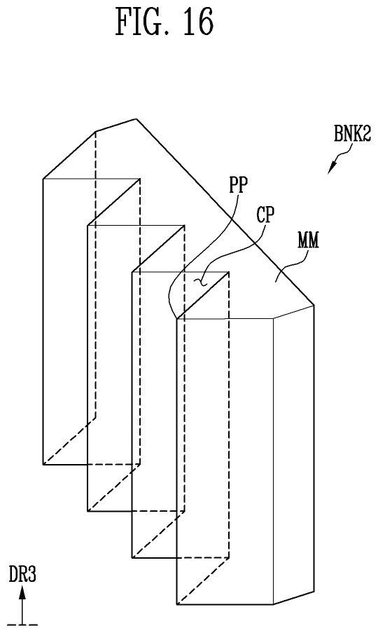

FIGS. 12 to 15 are schematic enlarged views of area EA1 of FIG. 6. FIGS. 12 to 15 are schematic plan views each illustrating a second bank BNK2 and an emission area EMA adjacent to the second bank BNK2 in accordance with an embodiment. FIG. 16 is a schematic perspective view illustrating a second bank BNK2 in accordance with an embodiment.

FIG. 12 illustrates a planar structure of a second bank BNK2 in accordance with a first embodiment. Referring to FIG. 12, the second bank BNK2 in accordance with the first embodiment may include a main body MM, a protrusion PP, and a cavity portion CP. The protrusion PP may have a structure protruding from the main body MM of the second bank BNK2. The protrusion PP may protrude from the main body MM toward the light emitting elements LD (or the emission area EMA). The cavity portion CP may be an area that is relatively recessed by the formation of the protrusion PP. The cavity portion CP may be an area formed between adjacent ones of the protrusions PP. The cavity portion CP may be a valley area.

The second bank BNK2 may have an irregular peripheral line, in a plan view. For example, the second bank BNK2 may have a peripheral line having a curved shape. A side surface of the second bank BNK2 that faces the color conversion layer CCL may have a curved surface. For example, the protrusion PP of the second bank BNK2 may relatively protrude compared to the cavity portion CP, and may face the emission area EMA in which the light emitting elements LD are disposed. The cavity portion CP of the second bank BNK2 may be defined in an area that is relatively recessed compared to the protrusion PP and may face the main body MM of the second bank BNK2.

In an embodiment, the protrusion PP may have a sharply protruding end. For example, the protrusion PP may generally have a triangular shape. Accordingly, the cavity portion CP may generally have a sharply recessed end area.

For example, referring to FIG. 16, the side surface of the second bank BNK2 that faces the emission area EMA may include a protruding structure extending in a direction (e.g., a thickness direction of the base layer BSL) The protrusion PP may extend in the third direction DR3 (e.g., in the thickness direction of the base layer BSL), and may have a shape which is reduced in a width in a direction. In an embodiment, the protrusion PP may have a triangular prism shape, and in response thereto, the cavity portion CP may have a triangular prism shape. In an embodiment, an end of the cavity portion CP that is adjacent to the main body MM may extend in the third direction DR3. For example, to form the protrusion PP and the cavity portion CP, the second bank BNK2 may be formed to have a shape corresponding thereto. Here, an etching process may be performed in a direction from the top to the bottom to pattern the second bank BNK2, so that the protrusion PP may generally have a pillar shape (e.g., the triangular prism shape).

In an embodiment, at least some of particles for forming the color conversion layer CCL may be disposed in the cavity portion CP. For example, one or more selected from the group including the first quantum dot QD1, the second quantum dot QD2, and the scatterer SCT may be disposed in the cavity portion CP. For example, the first quantum dot QD1, the second quantum dot QD2, and the scatterer SCT each may have a size (e.g., a diameter or a semi-major radius) less than that of the area in which the cavity portion CP is defined. The color conversion layer CCL may be adjacent to (or disposed in the area enclosed by) the second bank BNK2 and may be provided in the cavity portion CP. Although the first quantum dot QD1, the second quantum dot QD2, and the scatterer SCT may be disposed adjacent to the light emitting elements LD, FIG. 12 illustrates an embodiment in which the first quantum dot QD1, the second quantum dot QD2, and the scatterer SCT are disposed in the cavity portion CP.

In an embodiment, since the second bank BNK2 has the protrusion PP and the cavity portion CP, particles (e.g., the first quantum dot QD1, the second quantum dot QD2, the scatterer SCT, and the like) for forming the color conversion layer CCL may be disposed adjacent to the light emitting elements LD.

Experimentally, due to the coffee ring effect, the particles for forming the color conversion layer CCL may have a tendency to be disposed in the perimeter of the second bank BNK2 that receives the color conversion layer CCL. The coffee ring effect refers to a phenomenon in which fine particles included in a fluid are located to be adjacent to the perimeter of a receptor that receives the fluid.

In an embodiment, because the perimeter of the second bank BNK2 is disposed adjacent to the light emitting elements LD, particles (e.g., the first quantum dot QD1, the second quantum dot QD2, the scatterer SCT, and the like) for forming the color conversion layer CCL that is more adjacent to the second bank BNK2 may be disposed more adjacent to the light emitting elements LD. In an embodiment, light emitted from the light emitting elements LD may be re-emitted through the color conversion layer CCL. In other words, the particles for forming the color conversion layer CCL may substantially function as light emitting bodies. In an embodiment, because the particles for forming the color conversion layer CCL may be more adjacent to the light emitting elements LD, light may be generally uniformly provided from the emission areas EMA.

For example, in an embodiment, the protrusion PP may be spaced apart from the light emitting elements LD by a first distance L1. In case that the light emitting elements LD are arranged in a direction, the first distance L1 may be the shortest distance between an element alignment line 120 defined by ends of the light emitting elements LD and a position of an apex of the protrusion PP. For example, the element alignment line 120 may be an imaginary line which connects the respective ends of the light emitting elements LD to each other when the light emitting elements LD are arranged in parallel. In an embodiment, the first distance L1 may be about 5 μm or less. As another example, the first distance L1 may be 2 about μm or less. In other words, the peripheral line of the second bank BNK2 may be satisfactorily adjacent to the light emitting elements LD.

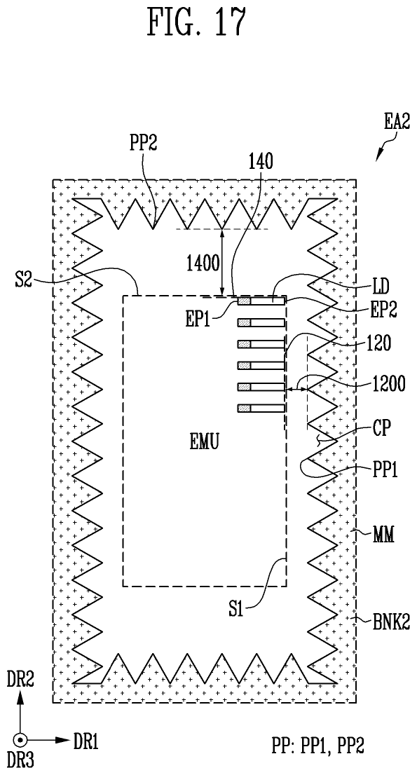

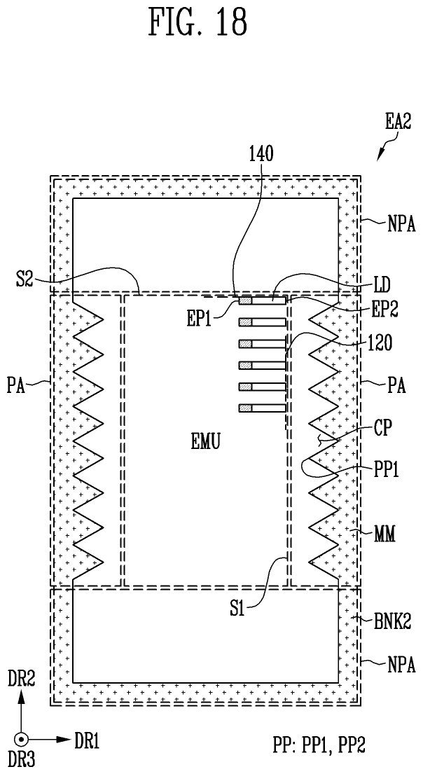

A density (or the number or the like) at which the protrusions PP are formed on the main body MM may vary depending on positions of the protrusions PP on the main body MM. In other words, the density at which the protrusions PP are formed may be designed to be changed depending on positions of the protrusions PP on the main body MM. Thus, the luminance of the emission area EMA of the pixel PXL may be further improved. Detailed description thereof is provided below with reference to FIGS. 17 and 18.

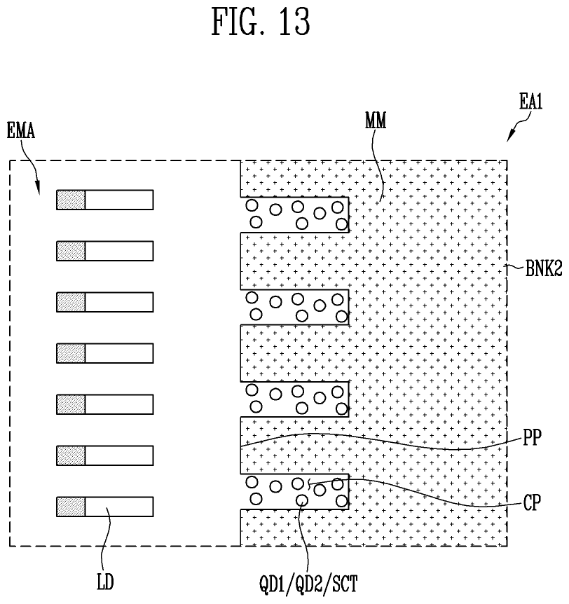

FIG. 13 illustrates a planar structure of a second bank BNK2 in accordance with a second embodiment. Referring to FIG. 13, the second bank BNK2 in accordance with the second embodiment is different from the second bank BNK2 in accordance with the first embodiment at least in that the protrusion PP has a rectangular shape.

In an embodiment, the protrusion PP may be adjacent to the emission area EMA and have a rectangular shape having two or more apexes. The cavity portion CP may have an area recessed in a rectangular shape having two or more apexes.

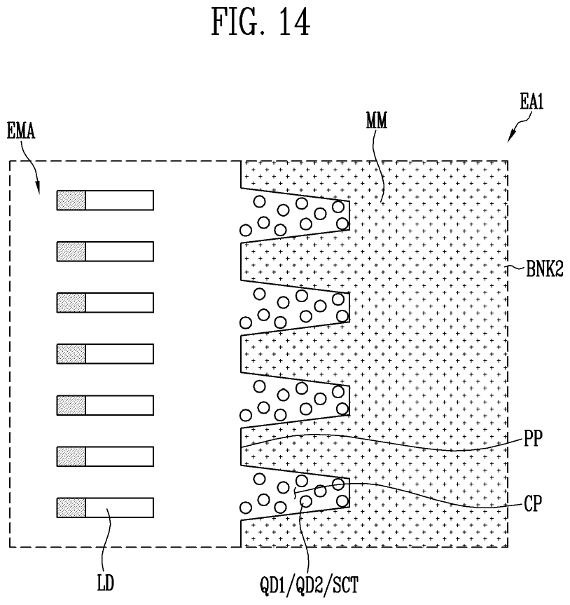

FIG. 14 illustrates a planar structure of a second bank BNK2 in accordance with a third embodiment. Referring to FIG. 14, the second bank BNK2 in accordance with the third embodiment is different from the second bank BNK2 in accordance with the first embodiment at least in that the protrusion PP has a trapezoidal shape.

In an embodiment, the protrusion PP may be adjacent to the emission area EMA and have a trapezoidal shape having two or more apexes. The cavity portion CP may have an area recessed in a trapezoidal shape having two or more apexes.

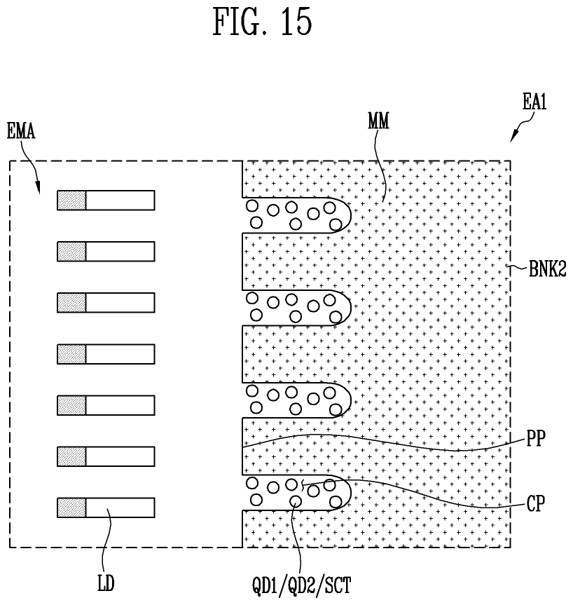

FIG. 15 illustrates a planar structure of a second bank BNK2 in accordance with a fourth embodiment. Referring to FIG. 15, the second bank BNK2 in accordance with the fourth embodiment is different from the second bank BNK2 in accordance with the second embodiment at least in that the cavity portion CP has a U-shape.

In an embodiment, the cavity portion CP may include an end area that has an overall curved shape. For example, referring to FIG. 15, the end of the cavity portion CP that faces the main body MM may have a curved shape, in a plan view.

FIG. 17 is a schematic enlarged view of area EA2 of FIG. 6. FIG. 17 is a schematic plan view illustrating a second bank BNK2 and emission areas EMA adjacent to the second bank BNK2 in accordance with an embodiment. FIG. 17 is a schematic plan view for describing a disposition structure of protrusions PP of the second bank BNK2.

Referring to FIG. 17, based on the emission component EMU, a position corresponding to a first side S1 and a position corresponding to a second side S2 may be different from each other in density at which the protrusions PP are patterned. For example, some of the protrusions PP at the first side S1 of the emission component EMU and others of the protrusions PP at the second side S2 of the emission component EMU may have different densities. For example, the protrusion PP may include first protrusions PP1 that face the first side S1 of the emission component EMU, and second protrusions PP2 that face the second side S2 of the emission component EMU. A density of the first protrusions PP1 that are disposed on the main body MM may be different from a density of the second protrusions PP2. The density of the protrusions PP1 and PP2 may refer to the number of protrusions PP1 and PP2 disposed in a unit surface area (or length) of the main body MM.

In an embodiment, at a side of an area from which light provided from the light emitting elements LD is emitted, the protrusion PP may be more adjacent to the emission component EMU. For example, the first protrusions PP1 and the emission component EMU may be spaced apart from each other by a first spacing distance 1200. The second protrusions PP2 and the emission component EMU may be spaced apart from each other by a second spacing distance 1400. The first spacing distance 1200 may be less than the second spacing distance 1400. The first spacing distance 1200 may be the shortest distance between a side edge (e.g., the first edge S1) of the emission component EMU with respect to the second direction DR2 and a position of an apex of the first protrusion PP1. The second spacing distance 1400 may be the shortest distance between a side edge (e.g., the second edge S2) of the emission component EMU with respect to the first direction DR1 and a position of an apex of the second protrusion PP2.

In an embodiment, the quantity of light emitted from the first side S1 may be greater than the quantity of light emitted from the second side S2. For example, light provided from the light emitting elements LD may be emitted (or provided) through the opposite ends EP1 and EP2 of each of the light emitting elements LD. In an embodiment, a direction in which the first side S1 extends may be substantially identical (or correspond) to a direction (e.g., the second direction DR2) in which the light emitting elements LD are successively arranged. A direction in which the second side S2 extends may be substantially identical (or correspond) to a direction (e.g., the first direction DR1) in which the light emitting elements LD substantially extend. The direction in which the first side S1 extends may be substantially identical to a direction in which the electrodes ALE for aligning the light emitting elements LD in the emission component EMU extend. The direction (e.g., the first direction DR1) in which the second side S2 extends may be substantially identical to a direction in which the electrodes ALE are spaced apart from each other in the emission area EMA (or in an area where the emission component EMU is formed). The second side S2 may extend in a direction (e.g., the first direction DR1) different from the direction (e.g., the second direction DR2) in which the electrodes ALE for aligning the light emitting elements LD in the emission component EMU extend. The second side S2 may correspond to an imaginary line that connects the first end EP1 to the second end EP2.

For example, each of the light emitting elements LD may be disposed to extend in the first direction DR1. The light emitting elements LD may be arranged (e.g., successively arranged) in the second direction DR2. The direction from the first ends EP1 of the light emitting elements LD to the second ends EP2 may be the first direction DR1. The light emitting elements LD may be more densely arranged in the second direction DR2. Hence, the intensity of light emitted from the first side S1 of the emission component EMU may be greater than the intensity of light emitted from the second side S2 of the emission component EMU. Because the density (e.g., the density of the light emitting elements LD) at which the first protrusions PP1 are disposed is selectively high in an area where the intensity of light is comparatively large, the number of particles for forming the color conversion layer CCL in an area adjacent to the first protrusions PP1 may be larger than that of an area adjacent to the second protrusions PP2. Hence, light provided from the emission component EMU may be efficiently emitted.

FIG. 18 is a schematic enlarged view of area EA2 of FIG. 6 and is a schematic plan view illustrating a pixel having a partially modified structure. FIG. 18 is a schematic plan view illustrating a second bank BNK2 and emission areas EMA adjacent to the second bank BNK2 in accordance with an embodiment. FIG. 18 is a schematic plan view for describing a disposition structure of the protrusions PP of the second bank BNK2.

Referring to FIG. 18, the second bank BNK2 may include a protruding area PA including protrusions PP and a non-protruding area NPA where the protrusions PP are not disposed. For example, the protrusions PP may be selectively disposed in only some areas to correspond to an area where the light emitting elements LD are disposed.

In an embodiment, the protruding area PA may overlap an emission component EMU in a direction (e.g., the first direction DR1) from first ends EP1 of the light emitting elements LD toward second ends EP2 of the light emitting elements LD. The non-protruding area PA may not overlap the emission component EMU in the direction (e.g., the first direction DR1) from the first ends EP1 of the light emitting elements LD toward the second ends EP2 of the light emitting elements LD. For example, the protruding area PA may correspond to a position at which light is emitted from the light emitting elements LD. In this case, the protrusions PP may be disposed to correspond to the position of a first side S1 at which the quantity of light provided from the light emitting elements LD is relatively large. In other words, depending on the disposition structure of the light emitting elements LD, the protrusions PP may be selectively (or intensively) in a main body MM, so that the emission efficiency of the pixel PXL may be further improved.

Due to the coffee ring effect according to the shapes of the protrusion PP and a cavity portion CP, the particles for forming a color conversion layer CCL may be more adjacent to a second bank BNK2. The coffee ring effect may be increased on a perimeter of the second bank BNK2 that corresponds to the position at which the density of the protrusions PP and the cavity portions CP are relatively high (or selectively formed). Hence, the particles for forming the color conversion layer CCL may be more intensively disposed at the position at which the protrusions PP and the cavity portions CP are disposed at a high density (or are selectively disposed). In other words, in an embodiment, the protrusions PP and the cavity portions CP may be disposed at a high density or selectively disposed at a position at which the intensity of generated light is relatively high, so that the positions of the particles for forming the color conversion layer CCL may be controlled. Accordingly, an increased number of particles for forming the color conversion layer CCL may be disposed at a position at which the intensity of generated light is relatively high, so that the luminance of the pixel PXL may be substantially enhanced.

Various embodiments of the disclosure may provide a display device that may uniformly emit light and have substantially improved luminance.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
light emitting elements on a base layer;
a bank on the base layer and protruding in a thickness direction of the base layer; and
a color conversion layer on the light emitting elements in an area adjacent to the bank, the color conversion layer including quantum dots that convert a color of a light,
wherein the bank includes:
a main body; and
protrusions protruding from the main body toward the light emitting elements.

2. The display device according to claim 1, wherein
the bank includes a cavity portion between the protrusions, and
the cavity portion has a valley structure.

3. The display device according to claim 1, wherein a peripheral shape of the color conversion layer and a peripheral shape of the bank correspond to each other, in a plan view.

4. The display device according to claim 1, further comprising:
a color filter layer including color filters; and
light blocking layers between the color filters, wherein
each of the color filters selectively transmits a light of a color,
the bank defines emission areas,
the light blocking layers define sub-pixel areas, and
the sub-pixel areas and the emission areas are different from each other.

5. The display device according to claim 4, wherein lights of different colors that are visible from an outside are respectively provided from the sub-pixel areas.

6. The display device according to claim 4, wherein
each of the sub-pixel areas is greater than each of the emission areas, and
at least part of each of the sub-pixel areas does not overlap each of the emission areas, in a plan view.

7. The display device according to claim 4, wherein each of the sub-pixel areas covers an entire area of each of the emission areas.

8. The display device according to claim 4, wherein the bank covers an entire area of the light blocking layer, in a plan view.

9. The display device according to claim 2, wherein the protrusions have at least one shape of a rectangular shape, a trapezoidal shape, and a triangular shape.

10. The display device according to claim 9, wherein the cavity portion includes an end area having a U-shape.

11. The display device according to claim 1, wherein
the light emitting elements are arranged in a direction,
ends of the light emitting elements are aligned in an element alignment line, and
a first distance that is a shortest distance between the element alignment line and the protrusions is about 5 μm or less.

12. The display device according to claim 1, wherein each of the protrusions has a pillar shape extending in the thickness direction of the base layer.

13. The display device according to claim 1, wherein
the light emitting elements form an emission component including a first side and a second side,
the protrusions comprise:
first protrusions corresponding to the first side; and
second protrusions corresponding to the second side, and
a shortest distance between the first side of the emission component and the first protrusions is less than a shortest distance between the second side of the emission component and the second protrusions.

14. The display device according to claim 13, wherein
a direction in which the first side extends is substantially identical to a direction in which the light emitting elements are successively arranged, and
a direction in which the second side extends is substantially identical to a direction in which the light emitting elements extend.

15. The display device according to claim 13, further comprising:
electrodes between the base layer and the light emitting elements,
wherein a direction in which the first side extends is substantially identical to a direction in which the electrodes extend in an area in which the emission component is disposed.

16. The display device according to claim 15, wherein a direction in which the second side extends is substantially identical to a direction in which the electrodes are spaced apart from each other in the area in which the emission component is disposed.

17. The display device according to claim 1, wherein
the light emitting elements form an emission component including a first side and a second side,
the protrusions comprise:
first protrusions corresponding to the first side; and
second protrusions corresponding to the second side, and
a density of the first protrusions on the main body is greater than a density of the second protrusions on the main body.

18. The display device according to claim 1, further comprising:
electrodes between the base layer and the light emitting elements;
a first connection electrode electrically connected to a first end of each of the light emitting elements; and
a second connection electrode electrically connected to a second end of each of the light emitting elements.

19. The display device according to claim 1, further comprising:
a color filter layer including color filters, wherein
each of the color filters selectively transmits a light of a color, and
the color conversion layer is between the base layer and the color filter layer.

20. A display device comprising:
light emitting elements provided on a base layer;
a color conversion layer on the light emitting elements and converting a wavelength of a light provided from the light emitting elements; and
a bank adjacent to at least part of the color conversion layer,
wherein a side surface of the bank that faces the color conversion layer has a curved surface.
